(19) United States
(12) Patent Application Publication
(10) Pub. No.: US 2026/0281582 A1
(43) Pub. Date: Sep. 17, 2026

(54) IMAGE SENSOR ASSEMBLY WITH DATA SIGNAL LINE FOR INTENSITY READOUT

(71) Applicant: Sony Semiconductor Solutions Corporation, Kanagawa (JP)

(72) Inventors: Erik Robert JOHANSSON, Stuttgart (DE); Rubén GÓMEZ MERCHÁN, Stuttgart (DE)

(73) Assignee: Sony Semiconductor Solutions Corporation, Kanagawa (JP)

(21) Appl. No.: 19/167,389

(22) PCT Filed: Mar. 13, 2024
(86) PCT No.: PCT/EP2024/056620

§ 371 Date: Sep. 22, 2025

(30) Foreign Application Priority Data
Mar. 30, 2023 (EP) 23165681.0

(51) Int. Cl. H04N 25/772; H04N 25/617; H04N 25/65

(52) U.S. Cl. CPC H04N 25/772; H04N 25/617; H04N 25/65

(57) ABSTRACT

An image sensor assembly includes pixel circuits, wherein each pixel circuit includes an amplifier transistor electrically coupled to a data signal line. A buffer transistor is electrically connected to the data signal line. The buffer transistor discharges the data signal line in an AD conversion period. The image sensor assembly further includes a detector circuit that includes a sensing path. The amplifier transistor, the buffer transistor, and the sensing path are electrically connected in series. The detector circuit outputs an active comparator output signal when a current through the sensing path exceeds a predefined threshold value.

The present disclosure relates to an image sensor assembly including data signal lines for intensity readout. More particularly, the present disclosure relates to a detector circuit for evaluating analog pixel signals transmitted via the data signal lines.

### BACKGROUND

An image sensor assembly for a solid-state imaging device includes photoelectric conversion elements that generate photocurrents proportional to the received radiation intensity. Pixel circuits convert the small photocurrents into analog voltage signals that are transmitted on data signal lines. For this purpose, each pixel circuit includes an amplifier transistor in a source follower configuration, wherein a constant current source connected to the data signal line operates as a shared source follower load for all pixel circuits connected to the same data signal line. Each amplifier transistor outputs its pixel signal on the data signal line at a different row selection interval. A downstream ADC (analog-to-digital converter) converts the analog pixel signals into digital pixel values.

### SUMMARY

The constant current source and the ADC contribute not insignificantly to the power consumption of the image sensor assembly. The present disclosure mitigates such shortcomings of the prior art. In particular, the present disclosure provides an image sensor assembly with a buffer transistor and a sensing path of a detection circuit electrically connected in series with the amplifier transistor of a pixel circuit. The data signal line can be set to a set potential. The buffer transistor can be variably controlled. In an AD conversion period of a row readout period, the buffer transistor gradually lowers the potential on the data signal line. When the potential of the data signal line begins to meet a predefined condition, the amplifier transistor turns on and a comparatively high current flows through the buffer transistor and the sensing path. The detection circuit senses the resulting current leap in the sensing path. The timing of the current leap depends, inter alia, on the voltage at the gate of the amplifier transistor and ultimately on the photocurrent. The pixel readout is dynamic and avoids a DC current on the data signal lines. The power consumption of the image sensor assembly during readout can be reduced with little additional effort.

Accordingly, an image sensor assembly in accordance with the present disclosure includes a pixel circuit including an amplifier transistor electrically coupled to a data signal line. A buffer transistor is electrically connected to the data signal line. The buffer transistor discharges the data signal line in an AD conversion period. The image sensor assembly further includes a detector circuit that includes a sensing path. The amplifier transistor, the buffer transistor, and the sensing path are electrically connected in series. The detector circuit outputs an active comparator output signal when a current through the sensing path exceeds a predefined threshold value.

The embodiments of the present disclosure use the amplifier transistors in the pixel circuits as part of the comparator portion of an analog-to-digital converter. The total current consumption for analog pixel readout and analog-to-digital conversion can be reduced.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings, wherein:

FIG. 1 is a simplified block diagram showing an image sensor assembly with the amplifier transistor of a pixel circuit, a buffer transistor, and a detector circuit sensing path electrically connected in series in accordance with an embodiment of the present technology.

FIG. 2 is a simplified block diagram showing a portion of an image sensor assembly with a ramp signal circuit controlling a buffer transistor in accordance with an embodiment of the present technology.

FIG. 3 is a simplified circuit diagram of a portion of an image sensor assembly with a buffer circuit including the buffer transistor in accordance with an embodiment.

FIG. 4 is a simplified circuit diagram of a buffer circuit including a comparator enable switch in accordance with an embodiment.

FIG. 5 is a simplified circuit diagram of a portion of a detector circuit including a current mirror circuit in accordance with an embodiment.

FIG. 6 is a simplified circuit diagram of a portion of a detector circuit including a low voltage cascode current mirror in accordance with an embodiment.

FIG. 7 is a simplified circuit diagram of a portion of a detector circuit including a low voltage cascode current mirror and constant current sources for the current mirror circuit in accordance with an embodiment.

FIG. 8 is a simplified circuit diagram of a portion of a detector circuit including a ramp autozeroing capacitor for the current mirror circuit in accordance with an embodiment.

FIG. 9 is a simplified circuit diagram of a detector circuit including leg switches for and comparator calibration and reducing power consumption in accordance with an embodiment.

FIG. 10 is a simplified circuit diagram of a portion of an image sensor assembly with a capacitance control line for the pixel circuits in accordance with an embodiment.

FIG. 11 is a simplified circuit diagram of a portion of an image sensor assembly detector circuit with a buffer circuit and a detector circuit in accordance with an embodiment providing an initialization of the data signal line with a voltage lower than a positive pixel supply voltage.

FIG. 12 is a simplified time diagram of various internal signals of the image sensor assembly of FIG. 11.

FIG. 13 is a simplified circuit diagram of a portion of an image sensor assembly detector circuit with a buffer circuit and a detector circuit in accordance with an embodiment providing an initialization of the data signal line with the positive pixel supply potential.

FIG. 14 is a simplified time diagram of various internal signals of the image sensor assembly of FIG. 13.

FIG. 15 is a simplified circuit diagram of a portion of an image sensor assembly detector circuit with a buffer circuit and a detector circuit in accordance with an embodiment providing a data signal line reset circuit for resetting the data signal line.

FIG. 16 is a simplified time diagram of various internal signals of the image sensor assembly of FIG. 15.

FIG. 17 is a schematic circuit diagram of a portion of an image sensor assembly having a row noise reduction unit in accordance with an embodiment with the amplifier transistor of a pixel circuit, a buffer transistor, and a detector circuit sensing path electrically connected in series.

FIG. 18 is a schematic circuit diagram of a portion of an image sensor assembly including a row noise reduction unit based on a noise signal generation unit and an interface transistor to a data signal line for analog pixel signals in accordance with an embodiment.

FIG. 19 is a schematic circuit diagram of an image sensor assembly including a row noise reduction unit based on a noise signal generation unit and an interface transistor to a data signal line for analog pixel signals in combination with a column signal processing unit including an analog-to-digital conversion unit for converting the analog pixel signals into digital pixel values in accordance with another embodiment.

FIG. 20 is a schematic block diagram of a solid-state imaging device comprising a digital core unit with a row noise estimation block in accordance with an embodiment.

FIG. 21 is a schematic diagram showing the variance of a noise distribution as a function of a parameter setting of a row noise reduction unit in accordance with an embodiment.

FIG. 22 is a diagram showing an example of a laminated structure of a solid-state imaging device according to an embodiment of the present disclosure.

FIG. 23 is a block diagram depicting an example of a schematic configuration of a vehicle control system.

FIG. 24 is a diagram of assistance in explaining an example of installation positions of an outside-vehicle information detecting section and an imaging section of the vehicle control system of FIG. 23.

### DETAILED DESCRIPTION

Embodiments for implementing techniques of the present disclosure (also referred to as “embodiments” in the following) will be described below in detail using the drawings. The techniques of the present disclosure are not limited to the described embodiments, and various features in the embodiments are illustrative only. The same elements or elements with the same functions are denoted by the same reference signs. Duplicate descriptions are omitted.

Connected electronic elements may be electrically connected through a direct, permanent low-resistive connection, e.g., through a conductive line. The terms “electrically connected” and “signal-connected” may also include a connection through other electronic elements provided and suitable for permanent and/or temporary signal transmission and/or transmission of energy. Electronic elements can be electrically connected or signal-connected via resistors, capacitors, electronic switches such as FETs (field effect transistors), or transistor circuits such as transmission gates. The load path of a transistor is the controlled path of a transistor. For example, a voltage applied to a gate of a FET controls by field effect the current flow in the load path between source and drain.

Though in the following a technology for reducing current consumption is described in the context of certain types of active pixel circuits, the technology may also be used for other types of active pixel circuits for intensity readout.

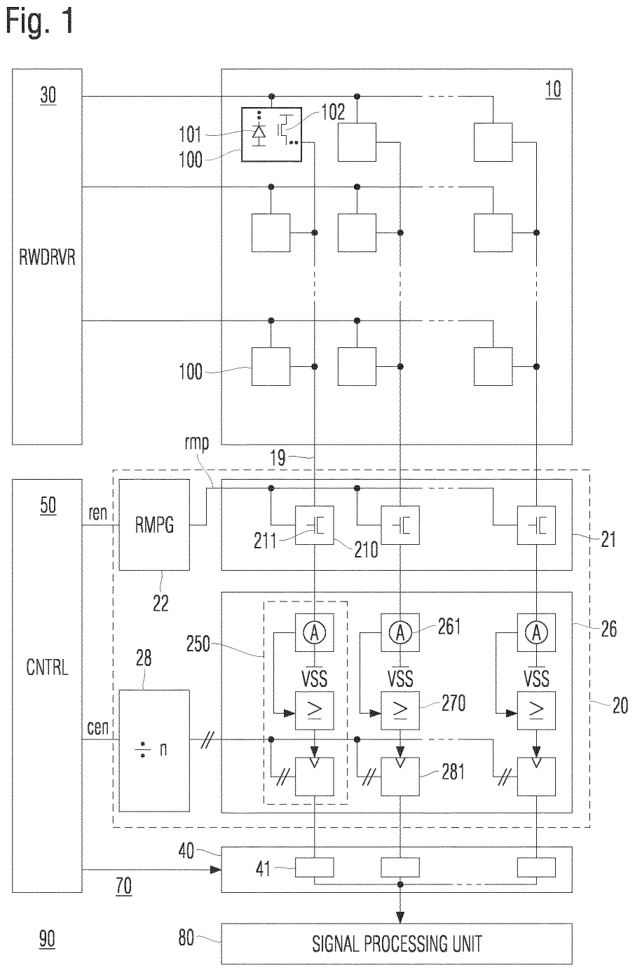

FIG. 1 illustrates a configuration example of a solid-state imaging device 90 including an image sensor assembly 70 in accordance with embodiments of the present technology and a signal processing unit 80. The image sensor assembly 70 includes a pixel array 10, a column signal processing unit 20, a row decoder/driver 30, a digital readout unit 40, and a sensor controller 50.

The pixel array unit 10 includes a plurality of identical pixel circuits 100. The pixel circuits 100 may be any active pixel sensors for intensity readout with one or two photoelectric conversion elements 101 and three, four or more FETs. When a pixel circuit 100 is selected, the pixel circuit 100 is signal-connected to a data signal line 19. Information about an internal voltage that depends on a illumination intensity detected by the pixel circuit 100 is available through the data signal line 19.

The photoelectric conversion elements 101 of the pixel array 10 may be arranged matrix-like in columns and rows. A subset of pixel circuits 100 assigned to the same column of photoelectric conversion elements 101 form a pixel column. A subset of pixel circuits 100 assigned to the same row of photoelectric conversion elements 101 form a pixel row.

The row decoder/driver 30 controls the pixel circuits 100. For this purpose, the row decoder/driver 30 generates pixel control signals for operating and selecting groups of pixel circuits 100. The pixel control signals control reset states, exposure time, internal temporal storage of the illumination information, and the readout of the pixel circuits 100.

The row decoder/driver 30 controls all pixel circuits 100 of a selected group of pixel circuits 100 synchronously. The selected group of pixel circuits 100 may include some pixel circuits 100 of one pixel row, all pixel circuits 100 of one pixel row, or some or all pixel circuits 100 of more than one pixel row. The following part of the description refers to “pixel rows” as examples for “groups of pixel circuits” for simplicity. The row decoder/driver 30 outputs the control signals for operating the FETs according to driver timing signals supplied from the sensor controller 50.

The pixel circuits 100 of a pixel output group sequentially pass information about an internal voltage that depends on an illumination intensity detected by the pixel circuits 100 to at least one data signal line (vertical signal line) 19. Each pixel output group may include some pixel circuits 100 of one pixel column, all pixel circuits 100 of one pixel column, or some or all pixel circuits 100 of more than one pixel column. The following part of the description refers to “pixel columns” as examples for “pixel output groups” for simplicity.

The pixel circuit 100 includes an amplifier transistor 102 that is in a source follower configuration with elements of the column signal processing unit 20. A load path of the amplifier transistor 102 is electrically connected between a pixel supply voltage VDDH and the data signal line 19. Each data signal line 19 sequentially conveys illumination information from the pixel circuits 100 of one of the pixel columns to the column signal processing unit 20.

The column signal processing unit 20 converts the analog pixel signals to digital pixel values. The column signal processing unit 20 includes a buffer unit 21, a ramp signal circuit 22, a comparator unit 26, and a counter circuit 28.

For each pixel column, the buffer unit 21 includes a buffer circuit 210 with a buffer transistor 211. A load path of the buffer transistor 211 is connected in series between the data signal line 19 of the pixel column and the comparator unit 26.

The ramp signal circuit 22 outputs a voltage ramp signal rmp. The voltage ramp signal rmp changes between a high level and a low level. In a ramp phase of the voltage ramp signal rmp, a slope of the voltage ramp signal rmp is shallow compared to the slope of other control signals output by the row decoder/driver 30. The voltage ramp signal rmp is applied to a gate of the buffer transistor 211. The shallow voltage ramp is applied during AD conversion periods of row readout periods. The buffer transistor 211 controls a gradually discharge of a parasitic capacitance of the data signal line (discharge of the data signal line) 19.

For each pixel column, the comparator unit 26 includes a detector circuit 250 with a sense path 261, a current monitor circuit 270 and a latch circuit 283. The sense path 261 of the detector circuit 250 is electrically connected in series between the buffer transistor 211 and a reference potential VSS. The current monitor circuit 270 monitors a current flow through the sense path 261 and outputs an active comparator output signal when the current monitor circuit 270 detects a leap in the current that flows through the sense path 261. The comparator output signal is applied to a control input of the latch circuit 283.

The counter circuit 28 outputs counter values of a digital counter. The counter values are applied to the data inputs of the latch circuits 283, wherein each latch circuit 283 is assigned to one of the pixel columns.

The latch circuit 283 latches a current (instantaneous) count value applied to the data inputs with a transition from an inactive comparator output signal to the active comparator output signal. The latched count value represents the digital pixel value of the signal obtained from the pixel circuit 100 in the AD conversion period.

Instead of one counter circuit 28 whose counter values are applied to all detector circuits, the column signal processing unit 20 may include one column counter for each detector circuit 250 or for each subset of the detector circuits 250. Instead of one ramp signal circuit 22 whose ramp signal rmp is applied to all buffer circuits 210, the column signal processing unit 20 may include one column ramp signal circuit for each buffer circuit 210 or for each subset of the buffer circuits 210.

The column signal processing unit 20 outputs the digital pixel values to a digital readout unit 40. The digital readout unit 40 includes a digital pixel memory for temporarily storing the digital pixel values for each pixel column. The digital readout unit 40 may include an arithmetic logic unit for preprocessing the stored digital pixel values. The arithmetic logic unit may calculate corrected pixel values from a digital pixel value obtained in a reset phase and a digital pixel value obtained from the same pixel circuit 100 in a data phase. The arithmetic logic unit may perform DCDS (digital correlated double sampling) by subtracting the digital pixel value obtained in a reset phase from the digital pixel value obtained from the same pixel circuit 100 in a data phase to obtain the corrected pixel value, wherein the data phase follows the reset phase in the same row readout period.

The sensor controller 50 generates the driver timing signal and outputs the driver timing signals to the row decoder/driver 30. The sensor controller 50 generates column control signals for controlling the column signal processing unit 20. In particular, the sensor controller 15 outputs a ramp enable signal for synchronizing the ramp signal circuit 22 and a counter control signal for synchronizing the counter unit 28. The sensor controller 15 may generate a readout control signal that controls the readout of digital pixel values from the digital readout unit 40 to the signal processing unit 80 and/or via a digital interface.

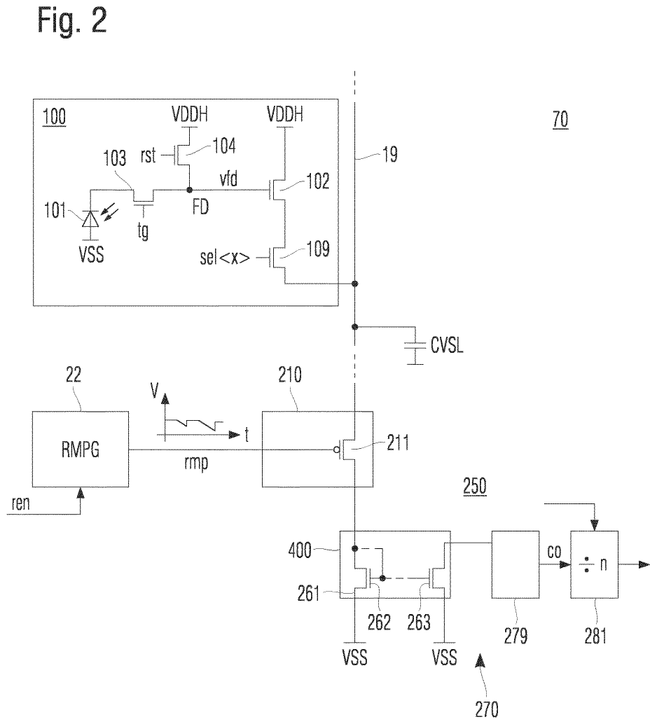

FIG. 2 shows a portion of the image sensor assembly 70 of FIG. 1.

The image sensor assembly 70 includes a pixel circuit 100, a buffer transistor 211, and a detector circuit 250. The pixel circuit 100 includes an amplifier transistor 102 electrically coupled to a data signal line 19. The buffer transistor 211 is electrically connected to the data signal line 19 and discharges the data signal line 19 in an AD conversion period. The detector circuit 250 includes a sensing path 261. The amplifier transistor 102, the buffer transistor 211, and the sensing path 261 are electrically connected in series. The detector circuit 250 outputs an active comparator output signal when a current through the sensing path 261 exceeds a predefined threshold value.

The buffer transistor 211 serves as a feed-in point for a voltage ramp signal rmp for analog-to-digital conversion of the signal at the gate of the amplifier transistor 102. In a ramp phase of the voltage ramp signal rmp, the buffer transistor 211 receives a variable voltage at the gate and discharges the data signal line 19 at an initially constant rate. The amplifier transistor 102 of a selected pixel circuit 100 turns on only when a voltage of the data signal line 19 and the voltage at the gate of the amplifier transistor 102 satisfy a predetermined relationship. When the amplifier transistor 102 turns on, a current through the sensing path 261 exhibits a current leap (current step). The detector circuit 250 detects the current leap. By continuously changing, e.g., lowering the voltage at the gate of the buffer transistor 211, a voltage difference between a data line set voltage at the start of the AD conversion and the voltage at the gate of the amplifier transistor 102 is converted into the length of a time interval between the start of the change in the voltage at the gate of the buffer transistor 211 and the current leap.

Compared to technologies that operate the amplifier transistor 102 in a source follower configuration with a constant current source as the load and use a separate differential comparator that receives an analog pixel signal from the source follower and the voltage ramp signal at two equivalent inputs, the analog-to-digital conversion according to the present disclosure includes fewer elements that consume current and almost all of the current is used to discharge a parasitic capacitance CVSL of the data signal line 19. Apart from that, the amplifier transistor 102 drives a significant amount of current only for a comparatively short response time after the current leap. In comparison, conventional analog-to-digital conversion of the analog pixel signals is based on operating the amplifier transistor 102 in a source follower configuration that includes a constant current source as load, wherein the constant current source supplies a significant current at least for the entire analog-to-digital conversion period.

The illustrated pixel circuit 100 includes a photoelectric conversion element 101 that photoelectrically converts incident electromagnetic radiation into electric charges. The amount of electric charge generated in the photoelectric conversion element 101 corresponds to the intensity of the incident electromagnetic radiation. The photoelectric conversion element 101 may include or consist of a photodiode which converts electromagnetic radiation incident on a detection surface into a detector current by means of the photoelectric effect. The electromagnetic radiation may include visible light, infrared radiation and/or ultraviolet radiation. The amplitude of the detector current corresponds to the intensity of the incident electromagnetic radiation, wherein in the intensity range of interest the detector current increases approximately linearly with increasing intensity of the detected electromagnetic radiation.

A floating diffusion FD stores charge supplied from the photoelectric conversion element 101 in a transfer period. A floating diffusion voltage vfd of the floating diffusion FD depends on the state of the pixel circuit 100: In a reset phase, the floating diffusion voltage vfd is a function of the pixel dark current. In a data phase, the floating diffusion voltage vfd is a function of the brightness (illumination intensity) sampled by the pixel circuit 100.

A load path of a transfer transistor 103 is electrically connected between a cathode of the photoelectric conversion element 101 and the floating diffusion region FD. The transfer transistor 103 serves as transfer element for transferring charge from the photoelectric conversion element 101 to the floating diffusion region FD in a transfer period. The floating diffusion region FD serves as temporary local charge storage. A transfer signal tg is supplied to the gate (transfer gate) of the transfer transistor 103 through a transfer control line. The transfer signal tg changes between an active signal level (“active transfer signal”) and an inactive signal level (“inactive transfer signal”). In response to an active transfer signal tg, the transfer transistor 103 transfers electrons photoelectrically converted by the photoelectric conversion element 101 to the floating diffusion region FD. In the illustrated embodiment, the active signal level is the high level. The amplifier transistor 102 is in a source follower configuration, with the controlled load path electrically connected between the positive pixel supply potential VDDH and the data signal line 19. The floating diffusion region FD is connected to the gate of the amplifier transistor 102. A potential at the gate of the amplifier transistor 102 is equal to the floating diffusion voltage vfd. The floating diffusion region FD functions as the input node of the amplifier transistor 102.

A load path of a reset transistor 104 is electrically connected between the positive pixel supply voltage VDDH and the floating diffusion region FD. The reset transistor 104 serves as a reset element that resets the floating diffusion potential vfd of the floating diffusion region FD. A pixel reset signal rst is supplied to the gate of the reset transistor 104 through a reset control line. The pixel reset signal rst changes between an active signal level (“active pixel reset signal”) and an inactive signal level (“inactive pixel reset signal”). In the illustrated embodiment, the active signal level is the high level. An active pixel reset signal rst sets the floating diffusion potential vfd equal to or approximately equal to a pixel reset voltage. The pixel reset voltage may be a fixed voltage, e.g., the positive pixel supply voltage VDDH, or may be adaptive and controlled by a threshold drift compensation circuit.

A plurality of pixel circuits 100 is connected to the same data signal line 19. The data signal line 19 has a parasitic capacitance CVSL. Each pixel circuit 100 includes a select transistor 109 to control a sequential readout of all pixel circuits 100 connected to the same data signal line 19. Load paths of the amplifier transistor 102 and the select transistor 109 are electrically connected in series between the positive pixel supply voltage VDDH and the data signal line 19. The select transistor 109 electrically couples the amplifier transistor 102 to the data signal line 19. In particular, the select transistor 109 connects the controlled load path between source and drain of the amplifier transistor 102 to the data signal line 19 when the pixel circuit 100 is selected and disconnects the amplifier transistor 102 from the data signal line 19 when the pixel circuit 100 is not selected.

A row select signal se1<x> for a pixel row x is supplied to the gate of the select transistor 109 through a select control line. The row select signal se1<x> changes between an active signal level (“active select signal”) and an inactive signal level (“active select signal”). In the illustrated embodiment, the active signal level is the high level.

An active row select signal se1<x> turns on the select transistor 109 for selection periods within each row readout period. When the select transistor 109 is on, the amplifier transistor 102 operates in a source-follower configuration and turns on when a potential on the data signal line 19 is sufficiently low for a given floating diffusion voltage vfd.

The gates of the transfer transistors 103, the gates of the reset transistors 104, and the gates of the select transistors 109 can be connected for groups of pixel circuits 100, e.g., pixel rows such that the operations can be simultaneously performed for each of the pixel circuits 100 of one group of pixel circuits 100, e.g., one pixel row.

In the illustrated configuration example, each pixel circuit 100 includes one photoelectric conversion element 101 and four nFETs (n-channel FETs) for controlling the pixel circuit 100. Other embodiments may refer to pixel circuits 100 with five or more than five FETs, and to pixel circuits 100 with two or more photoelectric conversion elements 101.

The amplifier transistor 102 of a selected pixel circuit 100 connected to the data signal line 19 and the buffer transistor 211 connected to the data signal line 19 are electrically connected in series so that a current flows through the serial connection in AD conversion periods.

The buffer transistor 211 operates as source follower. The voltage at the data signal line 19 follows the input voltage at the gate of the buffer transistor 211. When the buffer transistor 211 receives a linearly falling voltage at the gate, the voltage at the data signal line 19 decreases accordingly at an initially approximately constant rate. The buffer transistor 211 discharges the parasitic capacitance CVSL of the suitably pre-charged data signal line 19 at approximately constant rate, at least in an initial phase up to a point in time when the drain current of the amplifier transistor 102 exhibits the current leap.

A drain current ID_BUF of the buffer transistor 211 is given by a discharge current I_CVSL required to discharge the parasitic capacitance CVSL at a constant voltage slope, wherein I_CVSL=CVSL*dV/dt. The constant slope input voltage ramp results in a constant discharge current I_CSVL. The constant discharge current I_CSVL flows as drain current ID_BUF to the source of the buffer transistor 211. The constant drain current ID_BUF results in a constant gate-to-source voltage VGS at the buffer transistor 211.

At a certain point in time, the voltage on the data signal line 19 has sufficiently decreased such that the gate-to-source voltage VGS at the amplifier transistor 102 exceeds the gate threshold voltage of the amplifier transistor 102. The amplifier transistor 102 turns on. The drain current of the amplifier transistor 102 begins to increase exponentially and provokes a current leap in the sensing path 261. The timing depends on a data line set voltage for the pre-charged data signal line 19, the discharge rate, and the floating diffusion voltage vfd and is ultimately continuously (stepless) dependent on the brightness detected by the pixel circuit 100 during an exposure period.

The buffer transistor 211 may be a pFET (p channel FET), in particular, when a falling ramp at the gate is used for pixel readout. The controlled load path between source and drain of the amplifier transistor 102, the controlled load path between source and drain of the select transistor 109, the controlled load path between source and drain of the buffer transistor 211, and the sensing path 261 of the detector circuit 250 are electrically connected in series between, e.g., the positive pixel supply potential VDDH and a reference potential VSS.

The illustrated configuration example shows a sensing path 261 formed by the load path between source and drain of a sensing transistor 262. The detector circuit 250 includes a current comparator that compares a drain current ID_BUF of the buffer transistor 211 with a threshold current I_TH. For the illustrated embodiment, the threshold current I_TH is selected to be significantly greater than the discharge current I_CVSL. When the amplifier transistor 102 begins to turn on, the drain current ID_BUF of the buffer transistor 211 sharply increases and exceeds the threshold current I TH.

The detector circuit 250 may include further components to improve the sensitivity of the detector circuit 250 for low voltage swings across the sensing path 261, for cancelling the effect of device variations among the pixel circuits, and/or for compensating temperature-dependent effects.

In the illustrated embodiment, the detector circuit 250 includes a current monitor circuit 270 that outputs a digital comparator output signal co. The comparator output signal changes between an inactive signal level (“inactive comparator output signal”) and an active signal level (“active comparator output signal”). The comparator output signal co may be reset to the inactive signal level before the start of the discharge of the data signal line 19. The comparator output signal co becomes active when the amplifier transistor 102 begins to turn on, the drain current ID_BUF of the buffer transistor 211 sharply increases, and a current through the sensing path 261 exceeds a predefined threshold value characterizing the current leap. The predefined threshold value may be set to indicate that the gate-to-source voltage of the amplifier transistor 102 starts to exceed the gate threshold voltage of the amplifier transistor 102.

According to the illustrated configuration example, the current monitor circuit 270 includes a current mirror circuit 400 with the sensing transistor 262 in the input leg and an output transistor 263 in the output leg of the current mirror circuit 400.

From the output current of the current mirror circuit 400, an output stage 279 derives the comparator output signal co. An active comparator outputs signal co may latch a count value in the latch circuit 283 or may stop a column counter assigned to the pixel column.

The buffer transistor 211 is not operated as a switch, but as an analog device that continuously discharges the parasitic capacitance of the data signal line 19 at a predefined data line discharge rate. The data line discharge rate is slow compared to the rising and falling edges of other control signals used to control the pixel circuit 100.

The image sensor assembly 10 uses the time response when discharging the data signal line 19 to read out the pixel circuits 100. The combination of buffer transistor 211 and detector circuit 250 can be designed to be comparatively power-saving even in its basic form and also offers further possibilities to significantly reduce the consumed current with little additional effort.

The image sensor assembly 70 further includes a ramp signal circuit 22. The ramp signal circuit 22 generates a voltage ramp signal rmp that includes a ramp phase. The voltage ramp signal rmp or a signal derived from the voltage ramp signal rmp is supplied to the gate of the buffer transistor 211.

The voltage ramp signal rmp changes between a first level and a second level. The voltage ramp signal rmp includes constant-level phases with constant voltage level and ramp phases, in which the voltage level gradually changes at a rate, which is at least one order of magnitude or at least two orders of magnitude slower than a mean rate of rising edges and falling edge of other pixel control signals, e.g., the row select signal se1<x>. In particular, the slope of the ramp phases is sufficiently shallow so that the voltage at the data signal line 19 changes at a slow enough rate to let the detector circuit 250 detect the timing of an amplifier transistor turn-on with sufficient accuracy.

The slope of a voltage ramp in the ramp phases corresponds to Δvmax/Δtmax, wherein Δvmax can be the maximum usable voltage range at the data signal line 19, and wherein Δtmax can be the time it takes for the counter circuit 28 of FIG. 1 to count from 0 to the maximum counter value. A slope ΔV/Δt of the voltage ramp in the ramp phases may be in the order of 30 m V/μs to 6 V/μs. In contrast, a slope of control signals for the pixel array is in the order of 60 V/μs, and a slope of digital control signals in the solid-state imaging device is in the order of 2 k V/μs.

The ramp signal circuit 22 may include a counter and a digital-to-analog converter (DAC). The counter may reset a ramp count value to a preset value in response to a counter reset signal. In response to a ramp start signal, the counter may decrement the ramp count value at regular intervals. The DAC may generate a voltage ramp by converting the current ramp count value to an analog voltage proportional to the current ramp count value.

The ramp start signal and the counter reset signal can be controlled such that the ramp signal circuit 22 outputs a voltage ramp signal rmp that includes two falling voltage ramps per row readout period. For each falling voltage ramp, a voltage level of the voltage ramp signal rmp falls from a high voltage level in direction of a low voltage level. The low voltage level of the voltage ramp signal rmp may be equal to or slightly above the reference potential VSS.

The output of the ramp signal circuit 22 can be directly connected to the gate of the buffer transistor 211. Alternatively, the output of the ramp signal circuit 22 is electrically connected to an input-side electrode of a buffer input capacitor 215 and an output-side electrode of the buffer input capacitor 215 is electrically connected to the gate of the buffer transistor 211. The buffer input capacitor 215 may shift the voltage level of the voltage ramp signal rmp.

During a ramp phase of the signal applied to the gate of a p-channel buffer transistor 211, the buffer transistor 211 gradually discharges the data signal line 19 at a constant rate if and as long as the gate-to-source voltage at the amplifier transistor 102 in the selected pixel circuit 100 is lower than the gate threshold voltage of the amplifier transistor 102.

A pre-charge circuit pre-charges the data signal line 19 to a data line set voltage in a data line initialization period. The data line set voltage is sufficiently high that immediately after the data line initialization period the amplifier transistor 102 of each selected pixel circuit 100 is reliably off.

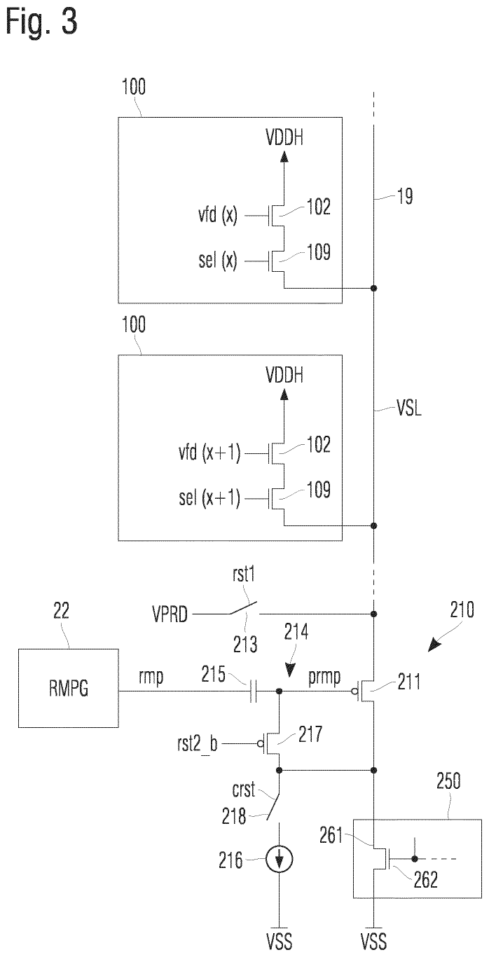

FIG. 3 shows details of data line initialization and of the buffer circuit 210 according to a configuration example.

The image sensor assembly 70 includes a sampling switch 213 that sets the data signal line 19 to a predefined potential VPRD in a data line initialization period.

The predefined potential VPRD may be the reference potential VSS, the pixel supply voltage VDDH, the logic supply voltage VDDL or any other available constant voltage. The predefined potential VPRD may set a data line set voltage at the end of the data line initialization period and immediately before an AD conversion period begins. Alternatively, the predetermined potential may set a data line initial voltage, from which the data line set voltage is reached by a subsequent charge or discharge of the data signal line 19 for a predefined period.

The sampling switch 213 may be an nFET (n-channel FET) when the predefined potential VPRD is equal to or close to the reference potential VSS. The sampling switch 213 may be a pFET (p-channel FET) when the predefined potential VPRD is equal to or close to the positive pixel supply voltage VDDH. Alternatively, the sampling switch 213 may include a pFET and an nFET with load paths electrically connected in parallel and controlled by the same gate signal. A first reset signal rst1 is supplied to control the sampling switch 213 through a first reset signal control line. The first reset signal rst1 changes between an active signal level (“active first reset signal”) and an inactive signal level (“inactive first reset signal”). In response to a first reset signal rst1, the sampling switch 213 connects the data signal line 19 with the predefined potential VPRD.

According to an embodiment, the image sensor assembly 70 may control the sampling switch 213 to connect the data signal line 19 to the predefined potential VPRD in a first portion of a data line initialization period and may control the buffer transistor 211 and/or the pixel circuit 100 to charge or discharge the data signal line 19 to a data line set voltage in a second portion of the data line initialization period.

For example, in the first portion of the data line initialization period the sampling switch 213 sets the data signal line 19 to a data line initial voltage which is lower than the positive pixel supply voltage VDDH. The second portion directly and seamlessly follows the first portion of the data line initialization period. During the second portion, one of the pixel circuits 100 is selected and the ramp signal rmp has a constant voltage level that turns off the buffer transistor 211.

The amplifier transistor 102 of the selected pixel circuit 100 charges the data signal line 19 to a data line set voltage that is higher than the data line initial voltage. The amplifier transistor 102 turns off and charging the data signal line 19 is terminated, when a voltage difference between the voltage on the data signal line 19 and the floating diffusion potential vfd falls below the threshold voltage of the amplifier transistor 102. The voltage of the data signal line 19 at the time the amplifier transistor 102 turns off gives the data line set voltage. The data line set voltage is a function of the data line initial voltage and the length of the second portion of the data line initialization period.

Alternatively, the data line initial voltage may be the positive pixel supply voltage VDDH and the buffer transistor 211 discharges the data signal line 19 to a data line set voltage in the second portion of the data line initialization period. This may reduce the KTC noise associated with the sampling switch 213, since if time goes to infinity, the voltage at the data signal line 19 is defined by the gate voltage of the buffer transistor 211 and an uncertainty in the start voltage level (data line set voltage) is irrelevant. Alternatively, the data line set voltage is set by a dedicated LVT sampled source follower in a column reset circuit.

The image sensor assembly 70 further includes a buffer autozero circuit 214 to obtain a pixel voltage ramp signal prmp applied to a gate of the buffer transistor 211 by subtracting a pixel-specific offset voltage from the voltage ramp signal rmp.

The same ramp signal circuit 22 and the same voltage ramp signal rmp can be used for the readout of a plurality of pixel circuits 100, e.g., for all pixel circuits 100 of a pixel column or for all pixel circuits 100 of the pixel array. The buffer autozero circuit 214 converts the global voltage ramp signal rmp into individual voltage ramp signals prmp for each pixel circuit 100 by subtracting the pixel-specific offset voltage from the global voltage ramp signal rmp.

The offset voltage is obtained for each pixel circuit 100 individually. Subtracting the pixel-specific offset voltage from the global voltage ramp signal cancels the effect of different threshold voltages of the amplifier transistors 102 and the buffer transistor 211 on the data line set voltage of the data signal line 19 at the beginning of the ramp phases of the voltage ramp signal. By applying the pixel-specific offset voltage, the data line set voltage on the data signal line 19 is made independent of manufacturing-based deviations and/or temperature-related deviations with respect to the threshold voltages of both the amplifier transistors 102 of different pixel circuits 100 and buffer transistors 211 of different pixel columns.

The illustrated buffer autozero circuit 214 includes a buffer input capacitor 215, an autozero current source 216, and an autozero transistor 217. The buffer input capacitor 215 receives a voltage ramp signal rmp at an input-side electrode. An output-side electrode of the buffer input capacitor 215 is electrically connected to a gate of the buffer transistor 211. The autozero current source 216 is configured to deliver a constant autozero current ILM through the amplifier transistor 102 of the selected pixel circuit 100 and through the buffer transistor 211 in a ramp buffer autozero period. The autozero transistor 217 is configured to connect the gate of the buffer transistor 211 with one side of a load path of the buffer transistor 211 in at least a portion of the ramp buffer autozero period.

The voltage ramp signal rmp can be a global voltage ramp signal generated by a single ramp signal circuit 22 as illustrated in FIG. 1 or a voltage ramp signal generated per pixel column.

The autozero transistor 217 may is a pFET. An auxiliary reset signal rst2_b is applied to a gate of the autozero transistor 217. The auxiliary reset signal rst2_b has a negative active voltage level to reliably turn on the autozero transistor 217 under low voltage conditions. The auxiliary reset signal rst2_b has a positive inactive voltage level to turn off the autozero transistor 217.

The autozero current source 216 is a constant current source supplying an autozero current ILM and may include an FET with a constant voltage applied to the gate.

Before the ramp buffer autozero period starts, the voltage vs1 on the data signal line 19 is set sufficiently low so that the amplifier transistor 102 of a reset and selected pixel circuit turns on and can charge the data signal line 19.

When the ramp buffer autozero period starts, the voltage ramp signal rmp has a constant high level, a pixel circuit 100 is selected, the autozero current source 216 is connected between the load path of the buffer transistor 211 and the reference potential VSS and the autozero transistor 217 is turned on. The amplifier transistor 102 of the selected pixel circuit 100, the buffer transistor 211 and the autozero current source 216 are electrically connected in series and the buffer transistor 211 is connected as diode via the turned-on autozero transistor 217. The amplifier transistor 102 of the selected pixel circuit 100 charges the data signal line 19 until the current flowing through the amplifier transistor 102 is equal to the autozero current ILM. The autozero transistor 217 passes the voltage at the data signal line 19 to the gate of the buffer transistor 211. When at the end of the ramp buffer autozero period the auxiliary reset signal rst2_b gets inactive and turns off the autozero transistor 217, the buffer input capacitor 215 stores a pixel-specific offset voltage. When later during the AD conversion periods the digital pixel values for the reset phase and the data phase are obtained, the pixel-specific offset voltage is subtracted from the voltage ramp signal and no offsets occur in the final image.

In the absence of the buffer autozero circuit 214, the auto-zero voltage level (data line set voltage) at the data signal line 19 varies for each pixel circuit 100. In contrast, by defining the pixel-specific offset voltage between the voltage ramp signal rmp and the pixel voltage ramp signal prmp, the buffer autozero circuit 214 associates the data line set voltages to the low voltage level of the voltage ramp signal rmp for each pixel circuit 100 individually and in this way compensates pixel-specific variations.

The illustrated autozero circuit 214 includes an autozero enable switch 218 that electrically connects the autozero current source 216 in series with a load path of the buffer transistor 211 in the ramp buffer autozero period and disconnects the autozero current source 216 from the buffer transistor 211 outside the ramp buffer autozero period.

The autozero enable switch 218 may be electrically connected in series with the load path of the autozero transistor 217. An active comparator reset signal crst turns on the autozero enable switch 218. In the illustrated example, the active level is the high level. A rising edge of the comparator reset signal crst and a trailing edge of the auxiliary reset signal rst2_b turning on the autozero transistor 217 may be synchronous. A rising edge of the auxiliary reset signal rst2_b turning off the autozero transistor 217 may slightly precede the trailing edge of the comparator reset signal crst.

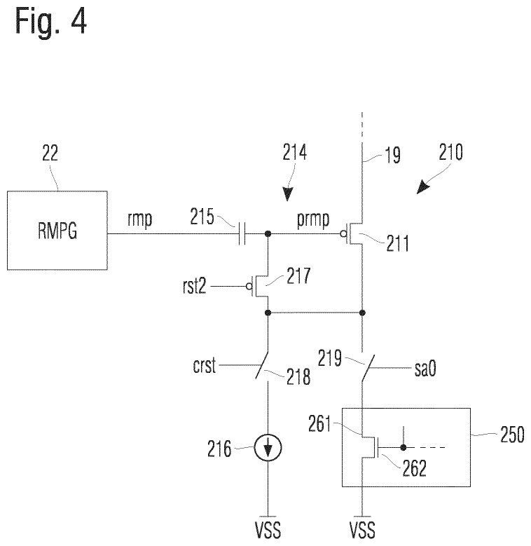

FIG. 4 shows a buffer circuit 210 that includes a comparator enable switch 219. The comparator enable switch 219 disconnects the sensing path 261 from a load path of the buffer transistor 211 outside the AD conversion periods.

The comparator enable switch 219 connects the detector circuit 250 with the load path of the buffer transistor 211 during at least a portion of each ramp phase. The comparator enable switch 219 disconnects the detector circuit 250 from the load path of the buffer transistor 211 at least for the complete time outside the ramp phases to reduce power consumption in the detector circuit 250. For example, a ramp enable signal REN may synchronously control both the output of the ramp phase of the voltage ramp signal rmp and the comparator enable switch 219. According to another example, a comparator input enable signal sa0 obtained by gating the ramp enable signal REN with the inverted comparator output signal co may control the comparator enable switch 219 to shorten the time of current flow through the sensing path 261 and to further reduce power consumption.

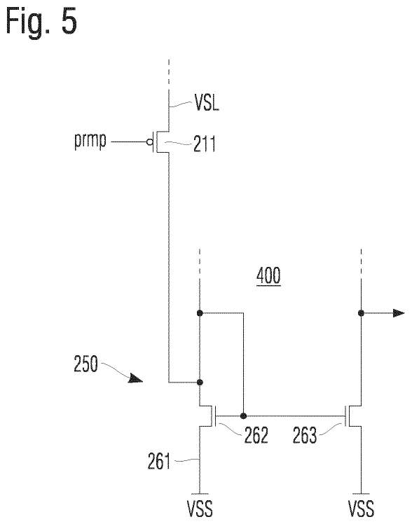

FIG. 5 shows a concept for a detector circuit 250 of an image sensor assembly according to the present technology.

The detector circuit 250 includes a current mirror circuit 400 that includes a first leg and a second leg. The first leg includes a sensing transistor 262. A load path between source and drain of the sensing transistor 262 forms at least part of the sensing path 261. The second leg includes an output transistor 263 controlled by the current through the sensing path 261.

The load path of the sensing transistor 262 is electrically connected between the load path of the buffer transistor 211 and the reference potential VSS. A gate of the sensing transistor 262 is electrically coupled to a drain of the sensing transistor 262 and to a gate of the output transistor 263. The first leg of the current mirror circuit 400 provides a low impedance path that allows the buffer transistor 211 to continuously discharge the data signal line 19.

The sensing transistor 262 and the output transistor 263 may be formed using the same technology parameters. The sensing transistor 262 and the output transistor 263 may have equal channel widths. Alternatively, the channel of the output transistor 263 may be wider than the channel of the sensing transistor 262. A ratio between the channel width of the output transistor 263 and the channel width of the sensing transistor 262 defines a current transfer ratio of the current mirror circuit 400 from the first leg to the second leg.

The sources of the sensing transistor 262 and the output transistor 263 may be connected to the same potential, e.g., to the reference potential VSS. The gates of the sensing transistor 262 and the output transistor 263 may be connected directly to each other or may be capacitively coupled to each other. The drain of the sensing transistor 262 may be connected to the gate of the sensing transistor 262 directly or through a first leg load.

With the drain and the gate of the sensing transistor 262 being electrically coupled, the current through the sensing path 261 sets the gate-to-source voltage of the sensing transistor 262, which in turn sets the gate-to-source voltage of the output transistor 263. The drain current through the output transistor 263 mirrors the current through the sensing path 261 and delivers the output current of the current mirror according to the current transfer ratio. For the current flow through the sense path 261, the current mirror circuit 400 provides a low impedance input, since the sensing transistor 262 is diode connected and looks like a resistor with R~1/gm.

The current mirror function ensures that the current in the second leg is strictly proportional to the current through the first leg. A significant change in the current in the first leg results in a significant change of the current through the second leg. The current in the second leg can be used to detect when the potential on the data signal line 19 falls below the potential at the gate of the amplifier transistor 102 minus the threshold voltage of the amplifier transistor 102.

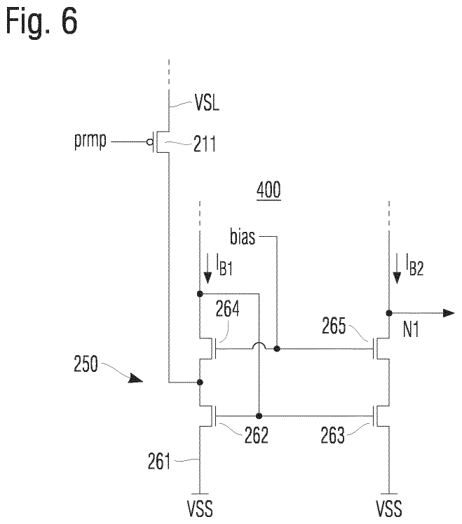

FIG. 6 refers to an improved concept for a detector circuit 250 of an image sensor assembly according to the present technology.

The detector circuit 250 includes a first load transistor 264 that includes a load path electrically connected between a gate of the sensing transistor 262 and the load path of the sensing transistor 262, and a second load transistor 265 that includes a load path electrically connected in series with a load path of the output transistor 263.

The transistors 262, 263, 264, 265 are arranged as a cascode current mirror. More particularly, FIG. 6 shows a low voltage cascode current mirror as an example for a cascode current mirror. With the low voltage cascode current mirror, a minimum voltage vs1 at the data signal 19 is close to the comparatively low on-state drain-to-source voltage VDSon of the sensing transistor 262, whereas for the standard current mirror circuit 400 of FIG. 5 the minimum voltage vls at the data signal line 19 is equal to a threshold voltage VTS of the sensing transistor 262. Since the threshold voltage VTS of the sensing transistor 262 is significantly higher than the on-state drain-to-source voltage VDSon, the cascode current mirror configuration of FIG. 6 may facilitate a larger voltage swing for the voltage vs1 on the data signal line 19.

The first load transistor 264 is an nFET with a load path between source and drain electrically connected between the gate and drain of the sensing transistor 262 and with a first constant bias voltage applied to the gate. The second load transistor 265 is an nFET with a load path electrically connected in series between an output node N1 of the current mirror and the load path of the output transistor 263. A second constant bias voltage is applied to the gate of the second load transistor 265. The first and second constant bias voltages may be equal. The first and second load transistors 264, 265 may be formed according to the same technological parameters. The channel widths may be equal or may have a ratio equal to the current transfer A constant first bias current IB1 is delivered through the load path of the first load transistor 264. In the sensing transistor 262, the constant first bias current IB1 adds up to the current supplied through the buffer transistor 211 in the AD conversion period. At the start of a ramp phase, only a drain current of the buffer transistor 211 discharges the data signal line 19. When the data signal line 19 is sufficiently discharged such that the amplifier transistor in the selected pixel circuit starts conducting, the drain current of the sensing transistor 261 sharply increases. With the increasing drain current, the drain-to-source voltage across the sensing transistor 261 increases, and the gate-to-source voltage of the first load transistor 264 decreases accordingly. The first bias current IB1 then charges the gate of the sensing transistor 262 to keep constant the current flow through the first load transistor 264. The output transistor 263 and the second load transistor 265 mirror the drain current of the sensing transistor 262. The feedback mechanism across the first load transistor 264 ensures that an arbitrary large current can flow through the sensing transistor 261 to the reference potential VSS. In particular, the current mirror 400 can handle a large range of currents without any specific requirements put on the size of the first bias current IB1. The first bias current IB1 can be selected to set a suitable bandwidth of the feedback loop.

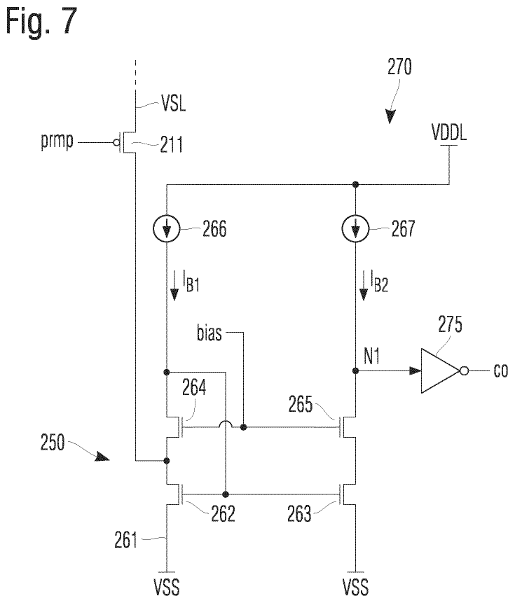

In FIG. 7, the detection circuit 250 includes a first leg current source 266 electrically connected in series with the sensing transistor 262, and a second leg current source 267 electrically connected in series with the output transistor 263.

The first leg current source 266 is electrically connected in series with the load path of the sensing transistor 262 between a high potential and the reference potential VSS. The high potential may be the pixel supply potential VDDH or the logic supply potential VDDL. For the illustrated cascode current mirror, the first leg current source 266, the load path of the first load transistor 264 and the load path between the drain and the source of the sensing transistor 262 are electrically connected in series between the logic supply potential VDDL and the reference potential VSS.

The second leg current source 267 is electrically connected in series with the load path of the output transistor 263 between a high potential and the reference potential VSS. The high potential may be the first supply potential VDDH or the second supply potential VDDL. For the illustrated cascode current mirror, the second leg current source 267, the second load transistor 265 and the load path of the output transistor 263 are electrically connected in series between the logic supply potential VDDL and the reference potential VSS.

The detector circuit 250 further includes a current monitor circuit 270 configured to output a digital comparator output signal co, wherein the comparator output signal co has a first signal level when the current through the output transistor 263 is lower than a reference current, and wherein the comparator output signal co has a second signal level when the current through the output transistor 263 is higher than the reference current.

For example, the comparator output signal co has an active signal level only when the current through the output transistor 263 is higher than the constant current IB2 supplied by the second leg current source 267. The current monitor circuit 270 further includes an inverter circuit 275. An input of the inverter circuit 275 is connected to the output node N1 between the second leg current source 267 and the load path of the second load transistor 265. The voltage at the output node N1 is high as long as the drain current of the output transistor 263 is low compared to the constant current IB2 supplied by the second leg current source 267. The voltage at the output node N1 becomes low when the drain current of the output transistor 262 is high compared to the constant current IB2 supplied by the second leg current source 267.

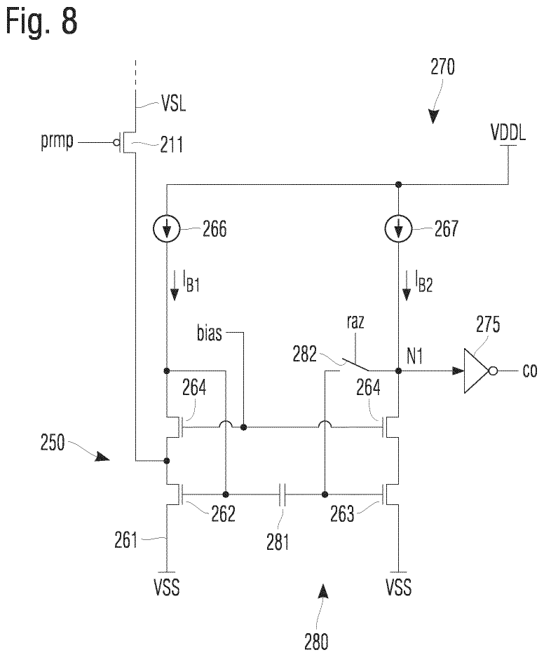

The detection circuit 250 in FIG. 8 includes an autozeroing circuit 280. The autozeroing circuit 280 stores information about an offset current flowing through the buffer transistor 211 in a comparator calibration period with no pixel circuit 100 selected and subtracts the offset current from a current flowing through the buffer transistor 211 during discharge of the data signal line 19 in an AD conversion period.

In the AD conversion period, one of the pixel circuits 100 connected to the data signal line 19 is selected. By subtracting, from the drain current ID_BUF of the buffer transistor 211 when any pixel circuit is selected, an offset current ID_BUF0, which is equal to the drain current of the buffer transistor 211 when no pixel circuit is selected, the detector circuit 250 responds only to the excess current induced by the pixel circuits 100 and does not respond to the unknown and potentially large ramp current.

Subtraction of the offset current may be provided at the data signal line 19 or at the node between the sensing transistor 262 and the first load transistor 264. The detector circuit 250 flips the digital comparator output signal co only when the current induced by the amplifier transistor 102 of a pixel circuit 100 is larger than the threshold current I_TH. The current-subtraction compensates the contribution of the ill-defined current discharge current I_CVSL for the parasitic capacitance of the data signal line 19 induced by the voltage ramp.

The autozeroing circuit 280 compensates the effect of the portion of the current through the buffer transistor 211 not induced by the amplifier transistor 102 of the selected pixel circuit 100. The autozeroing circuit 280 reacts only to an excess current from the pixel circuits 100 originating from the amplifier transistor 102 of the selected pixel circuit 100 and is to a high degree independent from the unknown and potentially large current induced by the ramp signal rmp. The ramp current autozeroing period may be performed once per frame or even less often, e.g., by inserting an idle row in the readout pattern.

In the illustrated embodiment, the autozeroing circuit 280 includes a ramp autozeroing capacitor 281 electrically connected between a gate of the sensing transistor 262 in the first leg and a gate of the output transistor 263 in the second leg. The detector circuit 250 is configured to store the ramp autozero voltage across the ramp autozeroing capacitor 281.

During an AD conversion period, the ramp autozero voltage effects that the offset current is subtracted from the drain current ID_BUF of the buffer transistor 211.

The autozeroing circuit 280 further includes a ramp autozeroing switch 282 electrically connected between an output node N1 and the gate of the output transistor 263, wherein the output node N1 is between the second leg current source 267 and the load path of the output transistor 263.

In the illustrated case of a cascode current mirror, the output node N1 is between the second leg current source 267 and the load path the second load transistor 265. The ramp autozeroing switch 282 is used to store the ramp autozero voltage across the ramp autozeroing capacitor 281.

An active comparator calibration signal raz turns on the ramp autozeroing switch 282 for the comparator calibration period and turns off the ramp autozeroing switch 282 outside the comparator calibration period. In the comparator calibration period, the drain current of the buffer transistor 211 discharges the data signal line 19 with a constant voltage slope in the ramp phase of the voltage ramp signal rmp with none of the pixel circuits 100 selected. When the ramp autozeroing switch 282 is on, both the sensing transistor 262 and the output transistor 263 are connected as diodes. The gate-to-source voltage of the sensing transistor 262 is determined by the drain current through the buffer transistor 211 and the constant current supplied by the first leg current source 266. The gate-to-source voltage of the output transistor 263 is determined by the constant current supplied by the second leg current source 266. The ramp autozero voltage is the difference between the gate-to-source voltage of the sensing transistor 262 and the gate-to-source voltage of the output transistor 263 and contains information derived from the drain current of the buffer transistor 211 in the comparator calibration period. When the ramp autozeroing voltage is later subtracted from a voltage obtained equivalently during the AD conversion periods, only negligible deviations of the buffer transistor drain current developing between the comparator calibration period and the AD conversion can become effective.

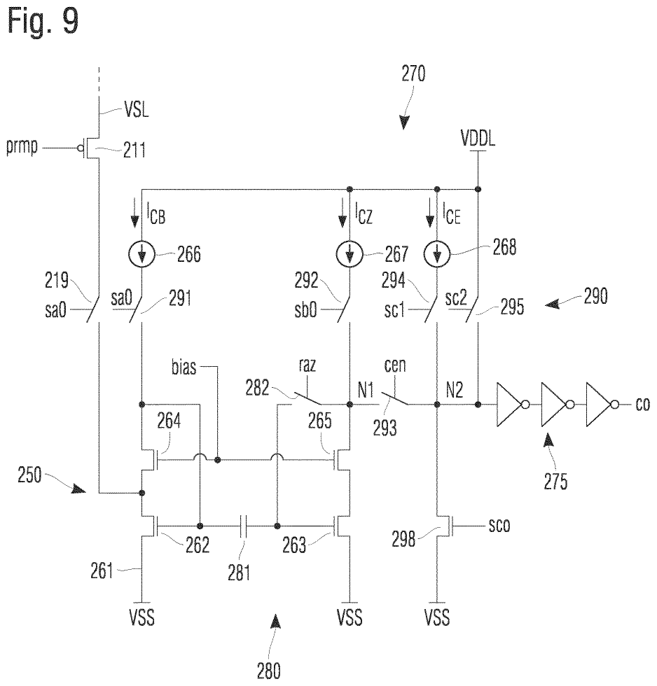

FIG. 9 shows a detection circuit 250 with further switches 291, 292, 293, 294, 295 that can be used to further reduce current consumption of the detection circuit 250.

The detection circuit 250 includes a first leg switch 291 configured to disable the first leg current source 266 at least outside the ramp phases, and/or a second leg switch 292 configured to disable the second leg current source 266 at least outside the AD conversion periods.

The first leg switch 291 may include an FET electrically connected in series with the first leg current source 266. The first leg switch 291 may be exclusively controlled by the ramp enable signal ren or by a gated ramp enable signal. For example, a comparator input enable signal sa0 obtained by gating the ramp enable signal ren with the inverted comparator output signal co controls the first leg switch 291.

The second leg switch 292 may include an FET electrically connected in series with the second leg current source 267. The second leg switch 292 may be exclusively controlled by the counter enable signal cen or by a gated counter enable signal. For example, a comparator output enable signal sb0 controls the second leg switch 292, wherein the comparator output enable signal sb0 is obtained by gating the counter enable signal cen with the inverted comparator output signal co, wherein the result of the gating can be ORed with the comparator calibration signal raz.

An auxiliary switch 294 and an auxiliary current source 268 are electrically connected between the positive logic supply voltage VDDL and an inverter input node N2 at the input of the inverter circuit 275. The auxiliary switch 294 may be exclusively controlled by the counter enable signal cen or by a gated counter enable signal. For example, an inverter input enable signal sc1 controls the auxiliary switch 294, wherein the inverter input enable signal sc1 is obtained by gating the counter enable signal cen with the inverted comparator output signal co.

By switching off the first leg current source, the second leg current source 266, and the auxiliary current source 268 when they are not needed, the current consumption in the detector circuit 250 can be further reduced.

A pull-down transistor 298 is electrically connected between the inverter input node N2 and the reference potential VSS. An inverter input disable signal sc0 controls the pull-down transistor 298, wherein the inverter input disable signal sc0 is obtained by gating the counter enable signal cen with the comparator output signal co. The pull-down transistor 298 pulls down the input of the inverter circuit 275 to a logic low level when in the AD conversion period the comparator output signal co becomes active.

A connection switch 293 is electrically connected between the output node N1 of the current mirror and the input node N2 of the inverter circuit 275. The counter enable signal cen controls the connection switch 293. When the counter enable signal cen is active, the connection switch 293 connects the output node N1 of the current mirror and the input node N2 of the inverter circuit 275. When the counter enable signal cen is inactive, the input node N2 of the inverter circuit 275 is disconnected from the output node N1 of the current mirror.

A comparator bypass switch 295 is electrically connected between the positive logic supply voltage VDDL and the inverter input node N2. A comparator bypass signal sc2 controls the comparator bypass switch 295, wherein the comparator bypass signal sc2 is the inverted counter enable signal cen. The comparator bypass switch 295 pulls up the input of the inverter circuit 275 to a logic high level to provide a stable inactive comparator output signal co when outside the AD conversion period most of the detection circuit 250 is deactivated.

The inverter circuit 275 can include an arbitrary odd number of inverters 274.

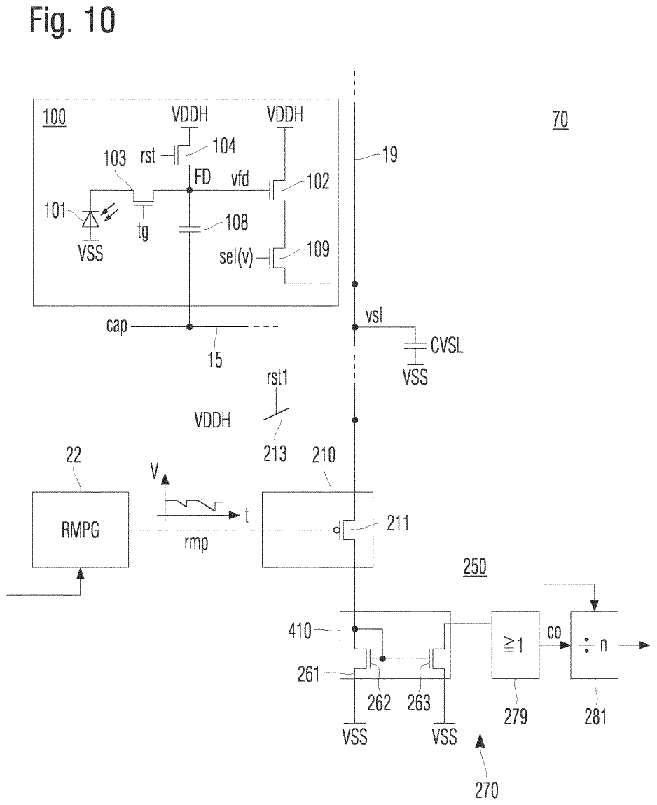

FIG. 10 shows a portion of an image sensor assembly 70 based on a type of pixel circuit 100 that can be used to further improve the present technology.

Each pixel circuit 100 of the illustrate image sensor assembly 70 includes a floating diffusion capacitance 108 electrically connected between a gate of the amplifier transistor 102 and a capacitance control line 15. The floating diffusion FD forms a first electrode of the floating diffusion capacitance 108. The capacitance control line 15 is connected to a second electrode of the floating diffusion capacitance 108 and passes a capacitance control signal cap from a row decoder of the image sensor assembly 70 to each pixel circuit 100 of a pixel row. Outside the AD conversion periods, a high level of the capacitance control signal cap may shift the effective gate-to-source voltage at the amplifier transistor 102 to a higher value, thereby reducing the time required for the precharge and ramp buffer autozero periods preceding the AD conversion periods. During the AD conversion periods, a low level of the capacitance control signal cap facilitates the operation of the pixel circuit 100 with the usual resolution and sensitivity.

The sampling switch 213 of the image sensor assembly 70 in FIG. 10 is configured to connect the data signal line 19 to a positive pixel supply potential VDDH.

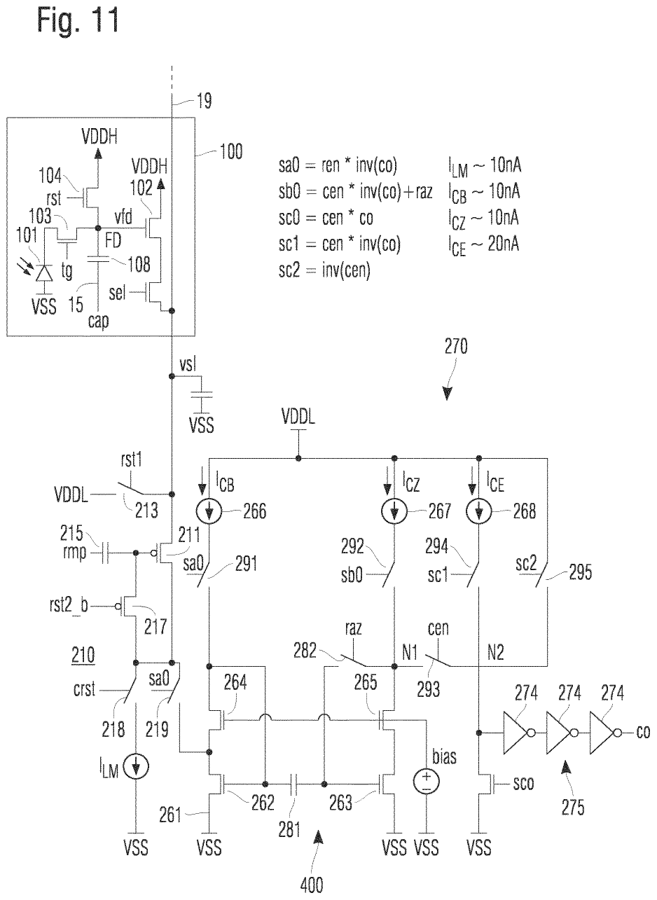

FIG. 11 shows a portion of an image sensor assembly 70 that includes a combination of a buffer circuit 210 as described with reference to FIG. 4 and a detection circuit 250 with a low voltage cascode current mirror as described with reference to FIG. 6, FIG. 7, FIG. 8 and FIG. 9.

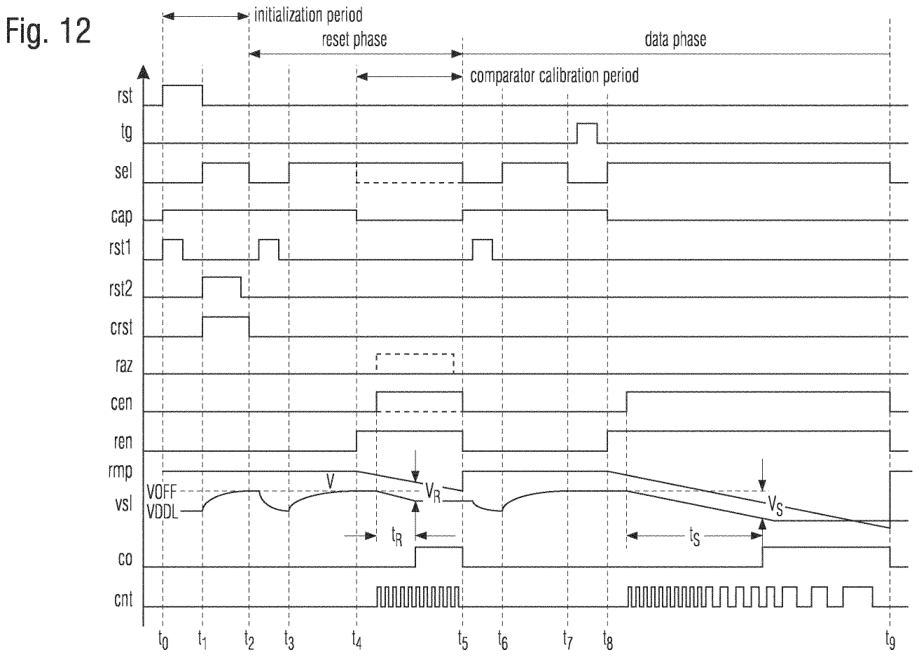

FIG. 12 shows some internal signals for a DCDS readout of the image sensor assembly 70 of FIG. 11 for a row readout period between t0 and t9. The row readout period includes an initialization period between t0 and t2, a reset phase between t2 and t5, and a data phase between t5 and t9.

The initialization period includes a pixel reset period between t0 and t1. The first reset signal rst1 is active and turns on the sampling switch 213. The sampling switch 213 sets the voltage vls of the data signal line 19 to the positive logic supply voltage VDDL. An active pixel reset signal rst turns on the reset transistor 104 and resets the floating diffusion potential vfd at the gate of the amplifier transistor 102 with the potential of the positive pixel supply voltage VDDH. The comparator bypass signal sc2 is active and turns on the comparator bypass switch 295. The comparator bypass switch 295 sets the input of the inverter 275 to the logic supply voltage VDDL corresponding to a logic high level.

The inverter circuit 275 outputs an inactive, logic low level comparator output signal co. The other switches of the buffer circuit 210 and the detector circuit 250 are off. None of the pixel circuits 100 is selected. The voltage ramp signal rmp has a constant high level. The capacitance control signal cap supplies a high level to the counter electrode of the floating diffusion FD.

For a ramp buffer autozero period between t1 and t2, an active select signal se1 turns on the select transistor 109 of a pixel circuit 100, the first reset signal rst1 gets inactive and turns off the sampling switch 213, the comparator reset signal crst gets active and turns on the autozero enable switch 218, and the second reset signal rst2 gets active such that the inverted and level-shifted auxiliary reset signal rst2_b turns to a sufficient low-level to turn on the autozero transistor 217.

Since the gate-to-source voltage at the amplifier transistor 102 at t1 is greater than the gate threshold voltage, the amplifier transistor 102 is on. Since the autozero enable switch 218 is on, the amplifier transistor 102 can charge the data signal line 19 to a turn-off voltage Voff at which the gate-to-source voltage of the amplifier transistor 102 falls below the gate threshold voltage and the amplifier transistor 102 turns off. The buffer transistor 211 is diode-connected and receives the turn-off voltage Voff at the gate. The turn-off voltage Voff is about the positive pixel supply voltage VDDH reduced by the gate threshold voltage of the amplifier transistor 102. When the second resistor signal rst2 gets inactive, the high level of the voltage ramp signal rmp and the turn-off voltage Voff define a pixel-specific offset voltage across the buffer input capacitor 215. For the following reset phase and the following data phase, the pixel-specific offset voltage is subtracted from the voltage ramp signal rmp to reduce the effect of variations of the threshold voltages of the amplifier transistor 102 and the buffer transistor 211.

The reset phase begins with a data line initialization period between t2 and t4. For a first portion of the data line initialization period between t2 and t3, the select signal se1 is inactive. The select transistor 109 is off and separates the pixel circuit 100 from the data signal line 19. The autozero enable switch 218, the autozero transistor 217 and the comparator enable switch 219 are off. The first reset signal rst1 is active and turns on the sampling switch 213. The sampling switch 213 discharges the data signal line 19 from a voltage near the positive pixel supply voltage VDDH to the positive logic supply voltage VDDL, which is lower than the positive pixel supply voltage VDDH.

For a second portion of the data line initialization period between t3 and t4, the first reset signal rst1 gets inactive and turns off the sampling switch 213. Instead, an active select signal se1 turns on the select transistor 109. Since the gate-to-source voltage at the amplifier transistor 102 at t1 is greater than the gate threshold voltage, the amplifier transistor 102 turns on and charges the parasitic capacitance of the data signal line 19. The data signal line voltage vs1 gradually rises and the drain current of the amplifier transistor 102 gradually decreases. The second portion of the data line initialization period is terminated by starting the AD conversion period for the reset phase. The AD conversion is started when the drain current of the amplifier transistor 102 is certainly much lower than the comparator current which is the sum of the current ICZ supplied by the second leg current source 267 and the current ICE supplied by the auxiliary current source 268. An appropriate positive capacitance control signal cap applied to the floating diffusion capacitance 108 via the capacitance control line 15 shortens the required time for the data line initialization period.

The AD conversion period of the reset phase between t4 and t5 starts with setting the ramp enable signal ren, and, if applicable, setting the capacitance control signal cap to a low level. The active ramp enable signal ren starts a first ramp phase of the voltage ramp signal rmp. The counter enable signal cen is set active and starts the counter. The rising edges of the ramp enable signal ren and the counter enable signal cen have a predetermined temporal relationship. The ramp enable signal ren sets active the comparator input enable signal sa0. The active comparator input enable signal sa0 turns on the comparator enable switch 219 between the buffer transistor 211 and the sensing path 261, and the first leg switch 291 in the first leg of the low voltage cascode current mirror circuit 400. The active counter enable signal cen sets active the comparator output enable signal sb0 and the inverter input enable signal sc1. The comparator output enable signal sb0 turns on the second leg switch 292 in the second leg of the cascode current mirror. The inverter input enable signal sc1 turns on the auxiliary switch 294. The active counter enable signal cen sets inactive the comparator bypass signal sc2. The inactive comparator bypass signal sc2 turns off the comparator bypass switch 295. The counter enable signal cen turns on the connection switch 293 that connects the output node N1 with the input of the inverter circuit 275. The detector circuit 250 is active.

The slowly falling voltage of the voltage ramp signal rmp gradually turns on the buffer transistor 211. The buffer transistor 211 gradually discharges the parasitic capacitance of the data signal line 19 and the voltage vs1 of the data signal line 19 gradually decreases. No or only a very small drain current flows through the amplifier transistor 102. The discharge current is the drain current of the buffer transistor 211 and is small at the beginning of the AD conversion period. The discharge current flows through the sensing path 261 of the low voltage cascode current mirror. The current through the second leg of the current mirror is defined by the currents supplied by the second leg current source 267 and the auxiliary current source 268.

When the voltage vs1 on the data signal line 19 falls below a threshold at which the amplifier transistor 102 begins to turn on, the current through the sensing path 261 grows exponentially and is mirrored to the drain current of the output transistor 263 of the current mirror. When the drain current of the output transistor 263 exceeds the sum of the currents ICZ, ICE supplied by the second leg current source 267 and the auxiliary current source 268, the voltage at the input of the inverter circuit 275 goes down and the comparator output signal co at the output of the inverter circuit 275 changes to an active high level. The rising edge of the comparator output signal co latches the count value, turns off all switches of the detector circuit 250 and the comparator enable switch 219, and turns on the temporary pull-down transistor 298 to keep the input of the inverter circuit 275 at the logic low level for the rest of the AD conversion period.

The time t_{R} between the rising edge of the counter enable signal cen and the rising edge of the comparator output signal in the reset phase is proportional to the amplitude of the noise signal of the pixel circuit 100 obtained in the reset phase.

The data phase begins with a further data line initialization period between t5 and t7. During the data line initialization period between t5 and t7 the signals can be controlled in the same way as in the data line initialization period between t2 and t4.

During a charge transfer period between t7 and t8, the pixel circuit 100 the select transistor 109 and all switches except the comparator bypass switch 295 are off. An active transfer signal tg turns on the transfer transistor 103 and the charge is transferred from the photoelectric conversion element 101 to the floating diffusion FD. A high voltage level of the capacitance control signal cap can improve the charge transfer.

The AD conversion period of the data phase between t8 and t9 follows the charge transfer period. During the AD conversion period of the data phase between t8 and t9, the signals can be controlled in the same way as in the AD conversion period of the reset phase between t4 and t5. The time tₛ between the rising edge of the counter enable signal cen and the rising edge of the comparator output signal co in the data phase is proportional to the voltage of the data signal of the pixel circuit 100 obtained in the data phase. The corrected pixel value is obtained by subtracting the count value obtained in the reset phase from the count value obtained in the data phase.

The dotted signals in FIG. 12 show the signals in a comparator calibration period. During the comparator calibration period, none of the pixel circuits 100 is selected. The comparator calibration period can be part of a row readout period for a non-existent row. Comparator calibration can be performed once per frame, e.g., in the vertical blanking period.

The control of the comparator calibration period differs from the control in the AD conversion period in that no pixel circuit 100 is selected, the counter enable signal cen stays inactive and instead the comparator calibration signal raz becomes active. The inactive counter enable signal cen turns on the comparator bypass switch 295 and deactivates the inverter input enable signal sc1 such that the auxiliary switch 294 turns off. The active comparator calibration signal raz turns on the ramp autozeroing switch 282. The first leg current source 266 supplies a current ICB through the first leg of the current mirror to the reference potential VSS. The second leg current source 267 supplies a current ICZ through the second leg of the current mirror to the reference potential VSS. The currents ICB and ICZ can be equal for a design of the current mirror with a current ratio of 1:1. The ramp autozeroing capacitor 282 is electrically connected symmetrically between the gates of the sensing transistor 262 and the output transistor 263 and between the drains of the first and second load transistors 264, 265.

When between t4 and t5 a voltage of the voltage ramp signal rmp gradually decreases, the drain current of the buffer transistor 211 discharges the parasitic capacitance of the data signal line 19. The drain current adds to the current through the sensing transistor 262. A voltage across the ramp autozeroing capacitor 282 depends on the drain current. When the comparator calibration signal raz changes to inactive, the comparator calibration signal raz turns off the ramp autozeroing switch 282 and the gate of the output transistor 263 floats. The voltage across the ramp autozeroing capacitor 282 is stored. In the following AD conversion periods, the stored voltage compensates the effect of a bias portion of the current through the sensing transistor 262 that originates from the drain current ID_BUF0 of the buffer transistor 211 when no pixel circuit is selected and that is equal to the discharge current I_CVSL.

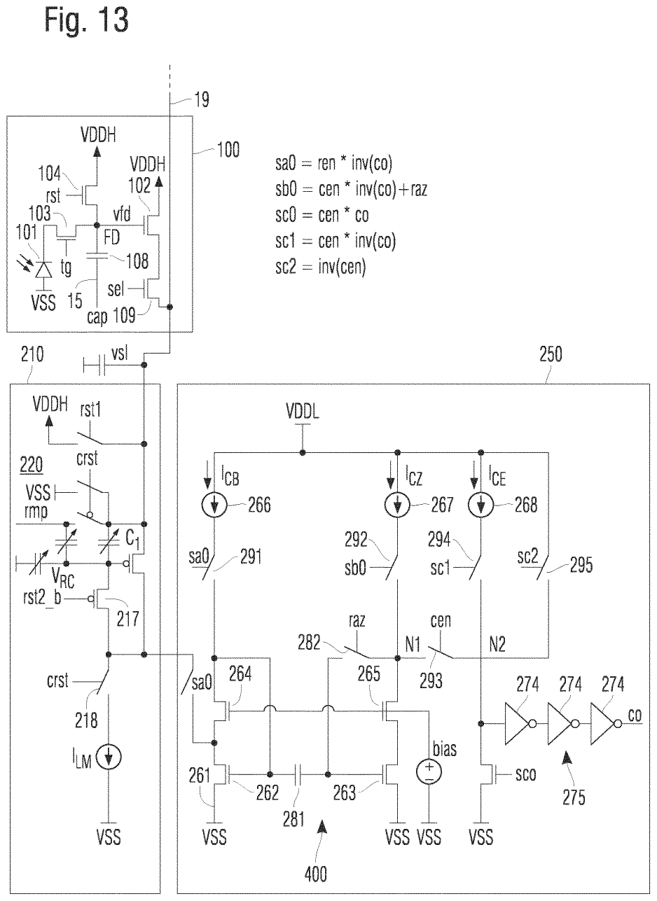

In FIG. 13, the sampling switch 213 of the image sensor assembly 70 is configured to connect the data signal line 19 to a positive pixel supply potential VDDH. The autozero operation for the pixel and ramp buffer threshold voltage variation can start from a comparatively high potential. To this end, the buffer autozero circuit 214 includes a further buffer input capacitor 212 between the gate of the buffer transistor 211 and a switched node. A comparator reset signal CRST switches the switched node to the reference potential VSS for the ramp buffer autozero period and to the ramp signal rmp outside the ramp buffer autozero period.

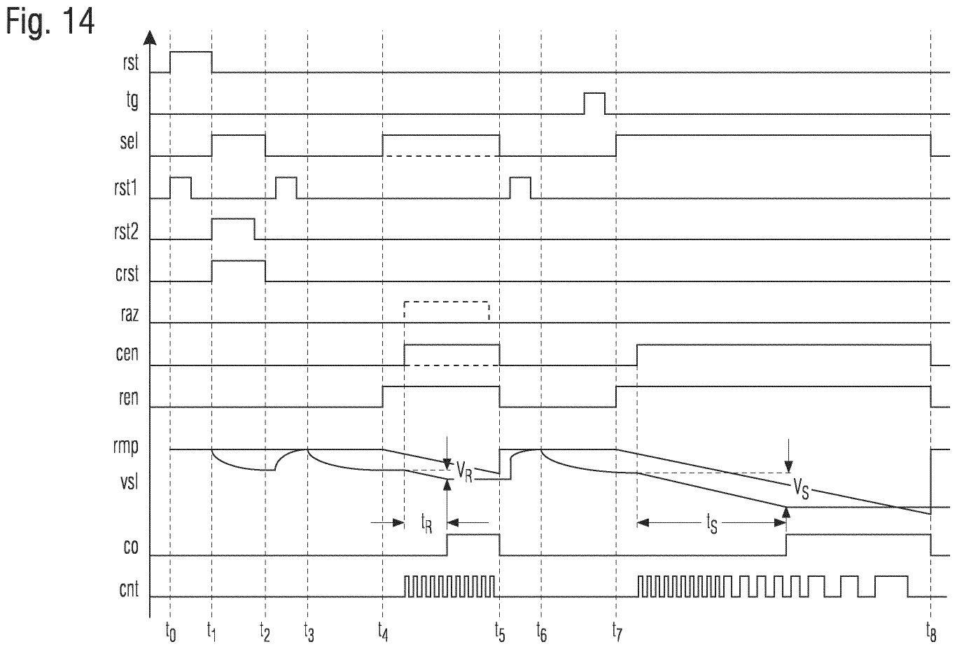

For the image sensor assembly of FIG. 13, FIG. 14 shows a row readout period between t0 and t8. The row readout period includes an initialization period between t0 and t2, a reset phase between t2 and t5, and a data phase between t5 and t8.

The initialization period includes a pixel reset period between t0 and t1. The first reset signal rst1 is active and turns on the sampling switch 213. The sampling switch 213 sets the voltage vls of the data signal line 19 to the positive pixel supply voltage VDDH.

For a ramp buffer autozero period between t1 and t2, the first reset signal rst1 gets inactive and turns off the sampling switch 213. Instead, the comparator reset signal crst gets active. The active comparator reset signal crst controls a change-over switch circuit 220 to apply a low voltage, e.g., the reference potential VSS to the gate of the buffer transistor 211 instead of the voltage ramp signal rmp. Then the buffer transistor 211 gradually discharges the parasitic capacitance of the data signal line 15 as long as the comparator reset signal crst is active. Compared to the initialization period of FIG. 11, FIG. 12, KTC noise associated with the sampling switch 213 can be reduced.

Since the pixel circuit 100 is no longer required for the initialization period, the data phase can merge the data line initialization period with the charge transfer period. During the data line initialization period between t5 and t7 the signals can be controlled in the same way as in the data line initialization period between t2 and t4, and in addition an active transfer signal tg can turn on the transfer transistor 103 to transfer the charge from the photoelectric conversion element 101 to the floating diffusion FD between t6 and t7.

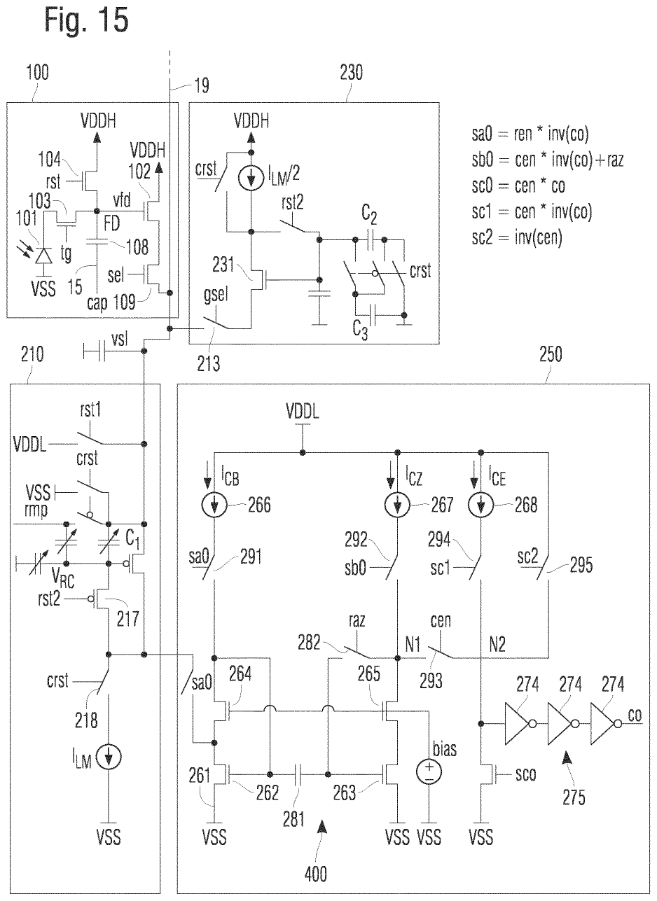

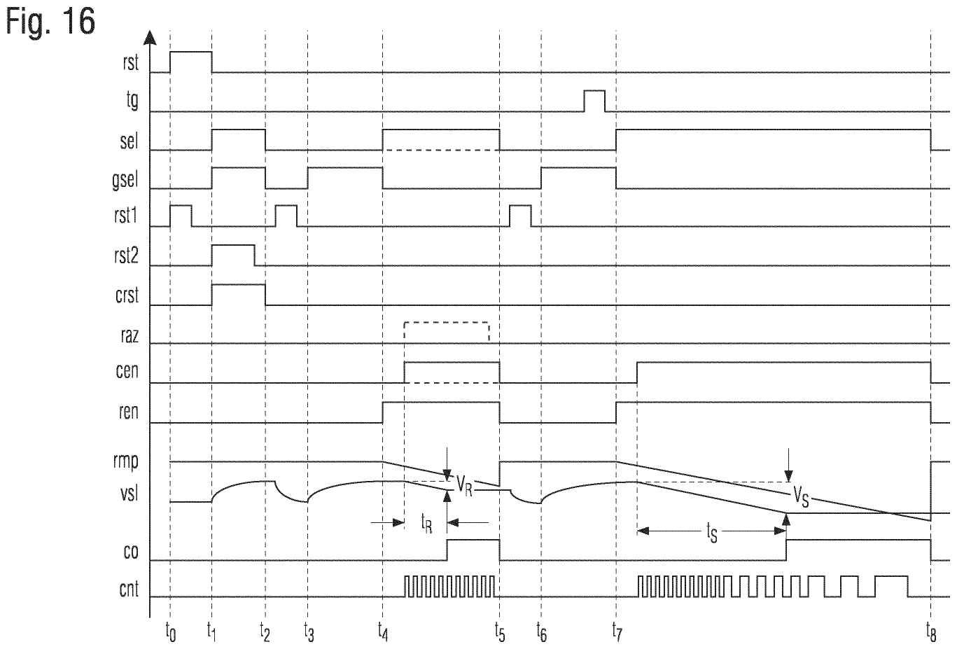

For the image sensor assembly 70 of FIG. 15, FIG. 16 shows a row readout period between t0 and t8. The row readout period includes an initialization period between t0 and t2, a reset phase between t2 and t5, and a data phase between t5 and t8.

The image sensor assembly 70 includes a column reset circuit 230. The column reset circuit 230 includes an LVT (low threshold voltage transistor) 231 in a source follower configuration.

In the pixel reset period between t0 and t1, the first reset signal rst1 is active and turns on the sampling switch 213. The sampling switch 213 sets the voltage vls of the data signal line 19 to the positive logic supply voltage VDDL.

For the ramp buffer autozero period between t1 and t2 and the second portions of the data line initialization periods between t3 and t4 and between t6 and t7, an active reset circuit enable signal gsel turns on a reset circuit enable switch 239 that connects the LVT 231 to the data signal line 19. The LVT 231 charges the parasitic capacitance of the data signal line 19 to a desired voltage. The column reset circuit 230 allows to select the data line set voltage for the AD conversion periods to reach a value that is independent from the properties of the amplifier transistors 102. In particular, the column reset circuit 230 sets the voltage vs1 on the data signal line 19 at t4−dt to a magnitude such that the amplifier transistor 102 of the selected pixel circuit 100 remains off until t4+td.

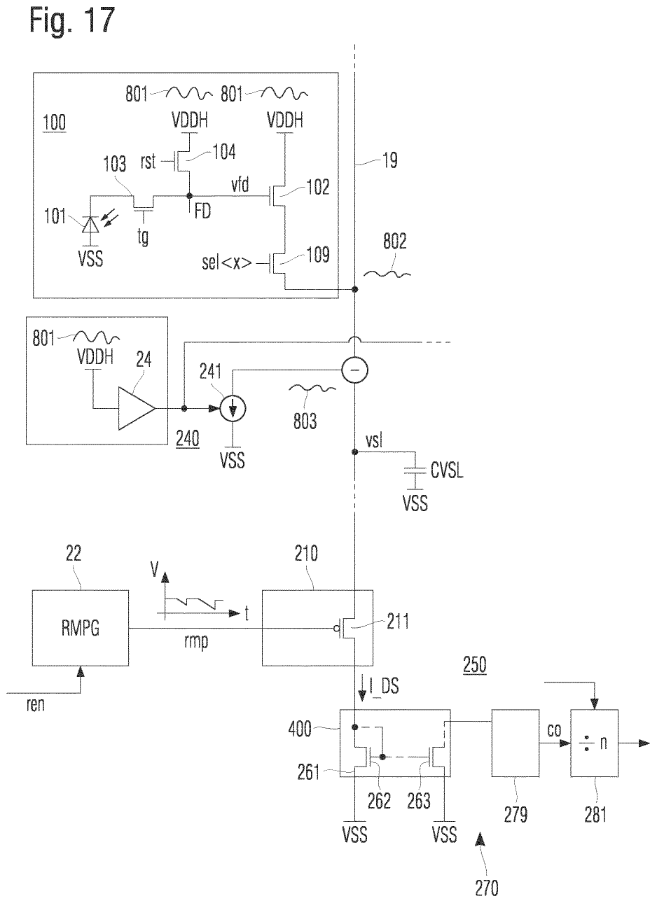

FIG. 17 shows an image sensor assembly 70 implementing high-frequency temporal noise reduction. Power supply noise on the positive pixel supply voltage VDDH may originate from capacitive and resistive coupling to the floating diffusions FD and/or the data signal line 19. The above-mentioned digital correlated double sampling reduces the effects of a low-frequency portion of the power supply noise. The high-frequency portion of the power supply noise causes row temporal noise in the captured images.

According to the illustrated embodiment, the image sensor assembly 70 includes a row noise reduction unit 240 that generates a noise compensation current from a positive pixel supply voltage VDDH electrically connected to the amplifier transistor 102 and applies the noise compensation current to the data signal line 19 to compensate a noise-induced current generated by power supply noise passed through the pixel circuit 100 to the data signal line 19.

The row noise reduction unit 240 may mitigate the effects of row temporal noise. The power supply noise 801 manifests in the form of random voltage fluctuations on the positive pixel supply voltage VDDH. At least during readout periods and/or autozero periods when one of the select transistors 109 connected to the data signal line 19 is on, the power supply noise 801 generates a noise-induced current 802 through the data signal line 19.

The row noise reduction unit 240 may be directly electrically connected to the positive supply voltage VDDH in a way that the same power supply noise 801 is effective for both the row noise reduction unit 240 and the pixel circuits 100 assigned to the concerned data signal line 19.

A transfer function of the pixel circuits 100 and a transfer function of the row noise reduction unit 240 are at least approximately equal. Then the row noise reduction unit 240 can generate a noise compensation current 803 from the positive supply voltage VDDH such that the noise-induced current 802 on the data signal line 19 and the noise compensation current 803 correlate to a high extent. The row noise reduction unit 240 may source the noise compensation current 803 to the data signal line 19 and/or may sink the noise compensation current 803 from the data signal line 19.

Applying the noise compensation current 803 directly to the data signal line 19 allows row temporal noise reduction even in the absence of comparator circuits with a first input receiving an analog pixel signal through the data signal line 19 and a second input receiving a ramp signal noise-compensated by another noise compensation signal.

In the illustrated embodiment, the row noise reduction unit 240 includes a noise compensation signal generation circuit 24 and controllable current sources 241. The noise compensation signal generation circuit 24 generates a noise compensation signal that qualitatively replicates the power supply noise 801. Each controllable current source 241 generates the noise compensation current for one data signal line 19 in response to the noise compensation signal.

The controllable current source 241 may include a FET, wherein a temporal noise at the gate of the FET must be sufficiently small in order to not generate row temporal noise. Then the noise compensation signal qualitatively replicates the voltage fluctuations caused by the power supply noise 801 on the positive pixel supply voltage VDDH. The term “qualitatively replicating” includes that for a predefined frequency range, the noise compensation signal and the power supply noise differ only in magnitude.

If the noise-induced current 802 induced on the data signal line 19 through the pixel circuits 100 and the noise compensation current 803 are in phase, the controllable current source 241 sinks the noise compensation current 803 from the data signal line 19. If the noise current 802 induced on the data signal line 19 through the pixel circuits 100 and the noise compensation current 803 are inverted signals, the controllable current source 241 sources the noise compensation current 803 to the data signal line 19.

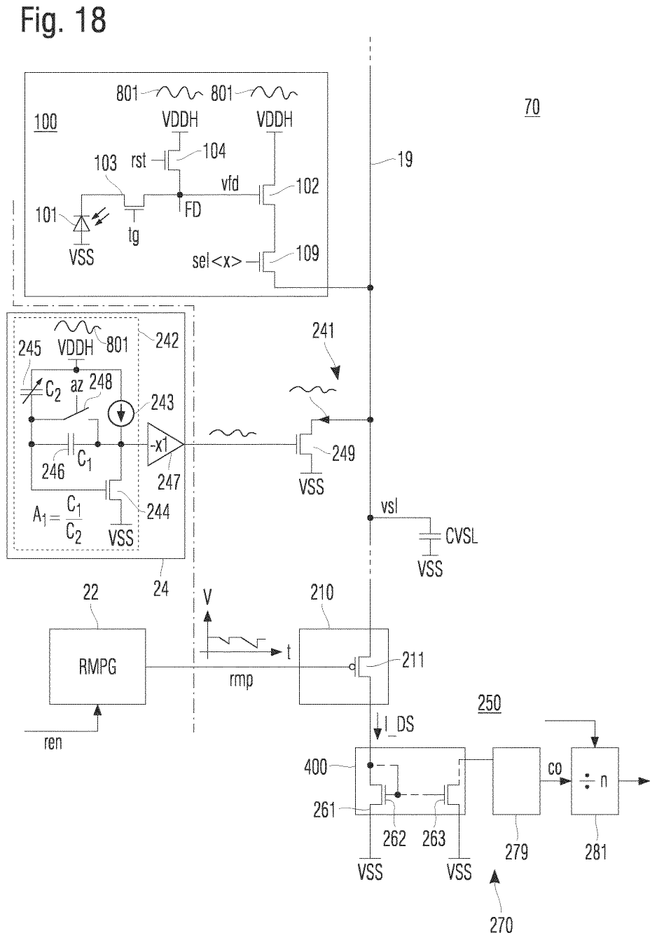

FIG. 18 shows an example of a global noise compensation signal generation circuit 24 providing the same noise compensation signal to a plurality of controllable current sources 241, wherein each controllable current source 241 is connected to another one of the data signal lines 19.

The noise compensation signal generation circuit 24 includes an amplifier circuit 242 with low pass characteristic. The amplifier circuit 242 includes a constant current source 243 and an amplification transistor 244, wherein the constant current source 243 and the controlled source-drain path of the amplification transistor 244 are electrically connected in series between the positive pixel supply voltage VDDH and the reference potential VSS. The output node of the amplifier circuit 242 is the node between the constant current source 243 and the amplification transistor 244.

An input capacitor 245 with a second capacitance C2 is electrically connected between the positive pixel supply voltage VDDH and the gate of the amplification transistor 244 and couples the positive pixel supply voltage VDDH to the gate of the amplification transistor 244. A feedback capacitor 246 with a first capacitance C1 is electrically connected between the output node of the amplifier circuit 242 and the gate of the amplification transistor 244. A controllable load path of an autozero transistor 248 may be electrically connected in parallel with the feedback capacitor 246.

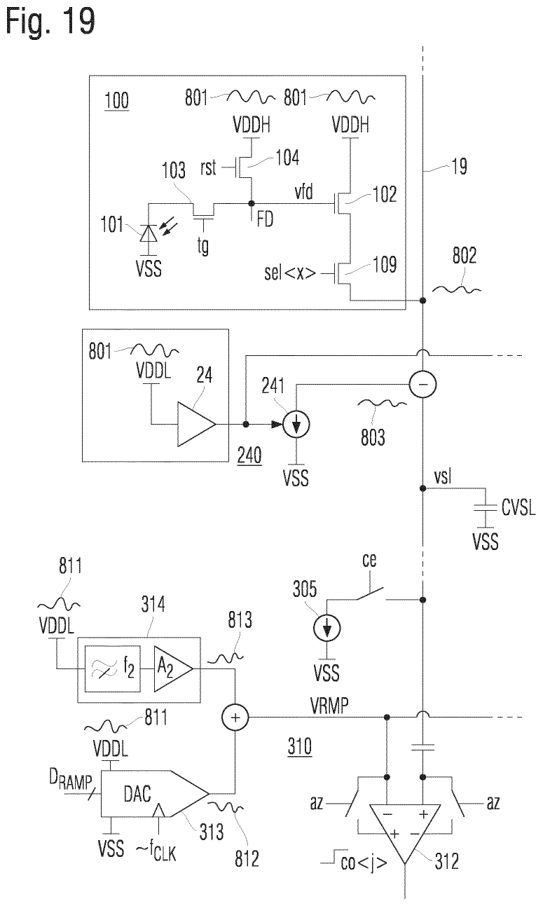

An active autozero signal az resets the amplifier circuit 242 by turning on the autozero transistor 248 for a ramp buffer autozero period between t1 and t2 in FIG. 12, FIG. 14 and FIG. 16 and/or a comparator autozero period for a comparator circuit 312 as illustrated in FIG. 19.

The output signal of the amplifier circuit 242 qualitatively replicates the power supply noise 801 on the positive pixel supply voltage VDDH at inverted amplitude. An analog inverter circuit 247 may invert the output signal of the amplifier circuit 242.

The gain A1 of the amplifier circuit 242 is given by the ratio between the first capacitance C1 of the feedback capacitor 246 and the second capacitance C2 of the input capacitor 245. The input capacitor 245 and the feedback capacitor 246 provide the same gain from f=0 to high frequency values. The analog inverter circuit 247 and the amplification transistor 244 provide the low-pass characteristic of the noise compensation signal generation circuit 24. The low-pass characteristic allows the noise compensation signal generation circuit 24 to cancel voltage steps at the positive pixel supply voltage typically occurring at the transition from a P phase to a D phase of a row readout period.

The output signal of the amplifier circuit 242 is applied to the gates of coupling NFETs 249 in common source configuration. The controlled load path of the coupling NFET 249 is electrically connected between a data signal line 19 and the reference potential VSS. The coupling NFET 249 is an embodiment of the controllable current source 241 in FIG. 17. Another embodiment of the controllable current source 241 in FIG. 17 may be a transmitter cascode.

A gain A1 of the noise compensation signal generation circuit 24 can be adjustable.

In the example of FIG. 18, the gain of the amplifier circuit 242 given by the ratio between the first capacitance C1 and the second capacitance C2 is adjustable by providing a tunable and/or programmable first capacitance C1 and/or a tunable/programmable second capacitance C2. For example, at least one of the first capacitance C1 and the second capacitance C2 includes a programmable capacitor array and the noise compensation signal generation circuit 24 is configured to receive digital coefficients at inputs of the programmable capacitor array.

The gain of the noise compensation signal generation circuit 24 can be adjusted once during a set-up procedure in a test phase of the image sensor assembly and/or may be steadily updated during operation of the of the image sensor assembly70.

FIG. 19 combines a row noise reduction unit 240 as described with reference to FIG. 17 and FIG. 18 with an image sensor assembly 70 that includes pixel circuits 100 outputting analog pixel signals on the data signal lines 19 and that further includes analog-to-digital converters 310 for converting the analog pixel signals into digital pixel values.

A constant current source 305 is connected to the data signal line 19 at least in the row readout periods such that the amplifier transistor 102 of a selected pixel circuit 100 operates as a source follower. The analog-to-digital converter 310 includes a comparator circuit 312 that receives the analog pixel signal at a first input. A row noise reduction unit 240 generates a noise compensation current for compensating the noise-induced current 802 induced in the data signal line 19 from the power supply noise 801 through the pixel circuit 100.

A digital-to-analog converter 313 outputs a voltage ramp signal VRMP that is applied to a second input of the comparator circuit 312. A positive logic supply voltage VDDL supplies the digital-to-analog converter 313. A supplemental row noise reduction unit 314 may generate a noise compensation signal 813 replicating an inverted row temporal noise 812 in the voltage ramp signal VRMP caused by power supply noise 811 passed from the positive logic supply voltage VDDL through the digital-to-analog converter 313. The noise compensation signal 813 and the voltage ramp signal VRMP are superimposed, wherein the noise compensation signal 813 at least partly compensates the row temporal noise 812 in the voltage ramp signal VRMP.

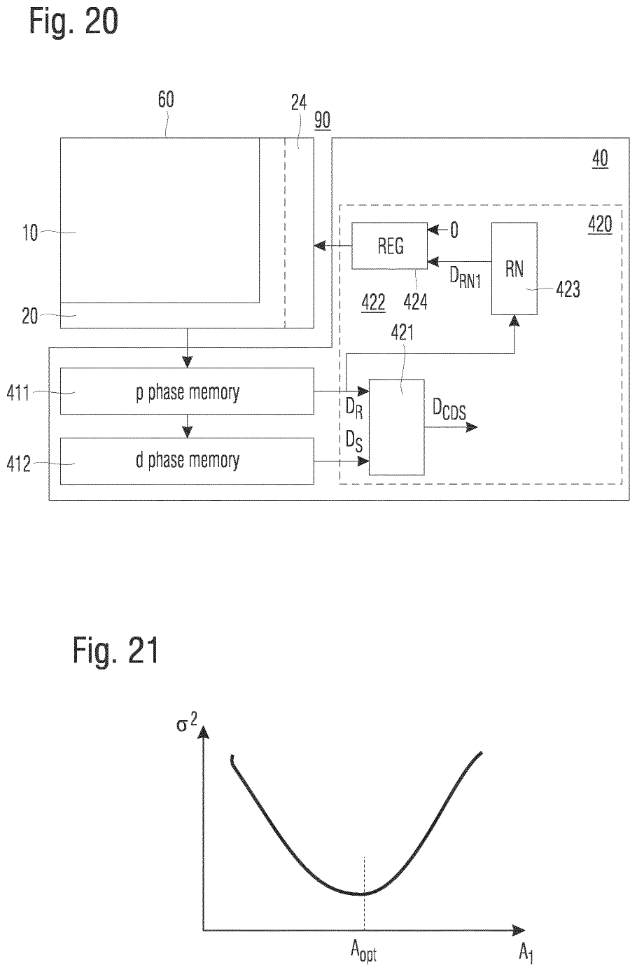

FIG. 20 illustrates an embodiment with a first digital pixel memory 411 that stores count values latched in response to the active comparator output signal, wherein the count values represent pixel noise values obtained from reset phases. A row noise estimation block 422 adjusts the gain of the noise compensation signal generation circuit 24 based on the pixel noise values.

Since the digital values obtained in the reset phases (pixel noise values) are obtained from non-illuminated pixel circuits, the pixel noise values image the non-compensated portion of the power supply noise. The row noise estimation block 422 can use the information about the non-compensated portion of the power supply noise to improve the noise compensation by selecting a more appropriate gain A1 for the noise compensation signal generation circuit 24.

In the block diagram of FIG. 20, the analog core 60 includes the pixel array 10 and the column signal processing unit 20 of FIG. 2. The column signal processing unit 20 includes a row noise reduction unit with a global noise compensation signal generation circuit 24 having an adjustable gain A1.

The column signal processing unit 20 outputs the digital pixel values to a digital readout unit 40. For each pixel column, the digital readout unit 40 includes a first digital pixel memory 411 for temporarily storing the digital reset values obtained in reset phases, and a second digital pixel memory 412 for temporarily storing the digital pixel values obtained in data phases (pixel data values).

A digital core 420 includes the row estimation block 422 and an arithmetic logic unit 421. The arithmetic logic unit 421 calculates corrected pixel values from the pixel noise value and the pixel data value obtained from the same pixel circuit 100 in the same row readout period. The arithmetic logic unit 421 may perform DCDS (digital correlated double sampling) by subtracting the pixel noise value from the pixel data value obtained from the same pixel circuit 100 to obtain the corrected pixel value, wherein the data phase follows the reset phase in the same row readout period. The row noise estimation block 422 receives the pixel noise values from the first digital pixel memory 411.

The row noise estimation block 422 adjusts the gain of the noise compensation signal generation circuit 24 to minimize a variance of the pixel noise values obtained from the reset phase.

The row noise estimation block 422 includes an estimator unit 423 and a regulator unit 424. The estimator unit 423 performs a recursive method for calculating the variance of a distribution of the pixel noise values, wherein the result of the recursive method is updated with each new pixel noise values. The recursive method may use Welford's algorithm. The estimator unit 423 may use the pixel noise values of one, some or all pixel columns.

The estimator unit 423 passes the calculated variance of a distribution of the pixel noise values to a regulator unit 424. The regulator unit 424 uses a control loop algorithm that uses the gain A1 of the noise compensation signal generation circuit 24 to drive a variance of the distribution of the pixel noise values to a minimum value.

For the targeted optimum setting of the programmable parameters of the first noise reduction unit 61, the variance has a minimum as illustrated in FIG. 21.

The digital core 420 may be completely implemented in hardware or completely in software or may include both hardware components and software components. For example, the digital core 420 may include an application specific integrated circuit (ASIC), a digital signal processor (DSP) and/or program code stored in a local program memory.

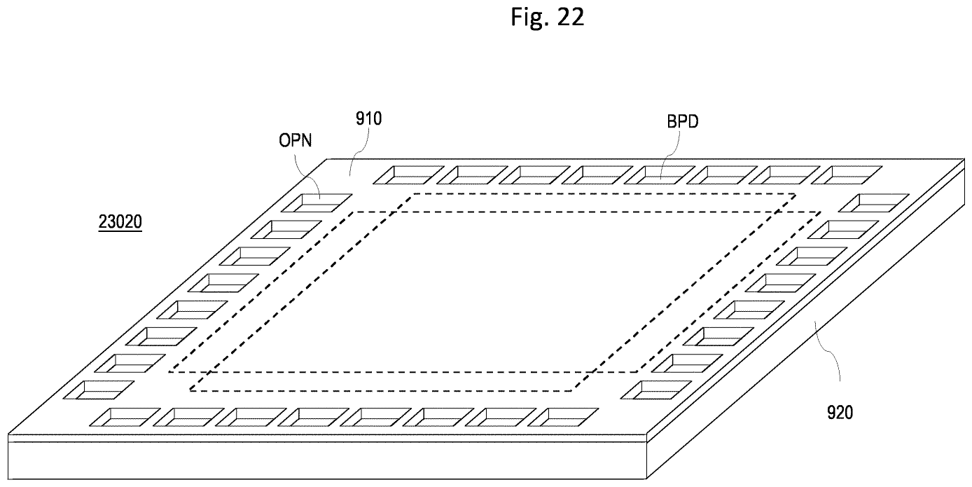

FIG. 22 is a perspective view showing an example of a laminated structure of a solid-state imaging device 23020 with a plurality of pixel circuits arranged matrix-like in array form. Each pixel circuit includes at least one photoelectric conversion element.

The solid-state imaging device 23020 has the laminated structure of a first chip (upper chip) 910 and a second chip (lower chip) 920.

The laminated first and second chips 910, 920 may be electrically connected to each other through TC(S)Vs (Through Contact (Silicon) Vias) formed in the first chip 910. Alternatively, the first and second chips 910, 920 include bond pads and corresponding bond pads are bonded together to form electrical connections during the process of laminating.

The solid-state imaging device 23020 may be formed to have the laminated structure in such a manner that the first and second chips 910 and 920 are bonded together at wafer level and cut out by dicing.

In the laminated structure of the upper and lower two chips, the first chip 910 may be an analog chip (sensor chip) including at least one analog component of each pixel circuit, e.g., the photoelectric conversion elements arranged in array form.

For example, the first chip 910 may include only the photoelectric conversion elements of the pixel circuits as described above with reference to the preceding FIGS. Alternatively, the first chip 910 may include further elements of each pixel circuit. For example, the first chip 910 may include, in addition to the photoelectric conversion elements, at least the transfer transistor, the reset transistor, the output transistor, and/or the source load of the pixel circuits. Alternatively, the first chip 910 may include each element of the pixel circuit.

The second chip 920 may be mainly a logic chip (digital chip) that includes the elements complementing the elements on the first chip 910 to complete pixel circuits and current control circuits. The second chip 920 may also include analog circuits, for example circuits that quantize analog signals transferred from the first chip 910 through the TCVs.

The second chip 920 may have one or more bonding pads BPD and the first chip 910 may have openings OPN for use in wire-bonding to the second chip 920.

The solid-state imaging device 23020 with the laminated structure of the two chips 910, 920 may have the following characteristic configuration:

The electrical connection between the first chip 910 and the second chip 920 is performed through, for example, the TCVs. The TCVs may be arranged at chip ends or between a pad region and a circuit region. The TCVs for transmitting control signals and supplying power may be mainly concentrated at, for example, the four corners of the solid-state imaging device 23020, by which a signal wiring area of the first chip 910 can be reduced.

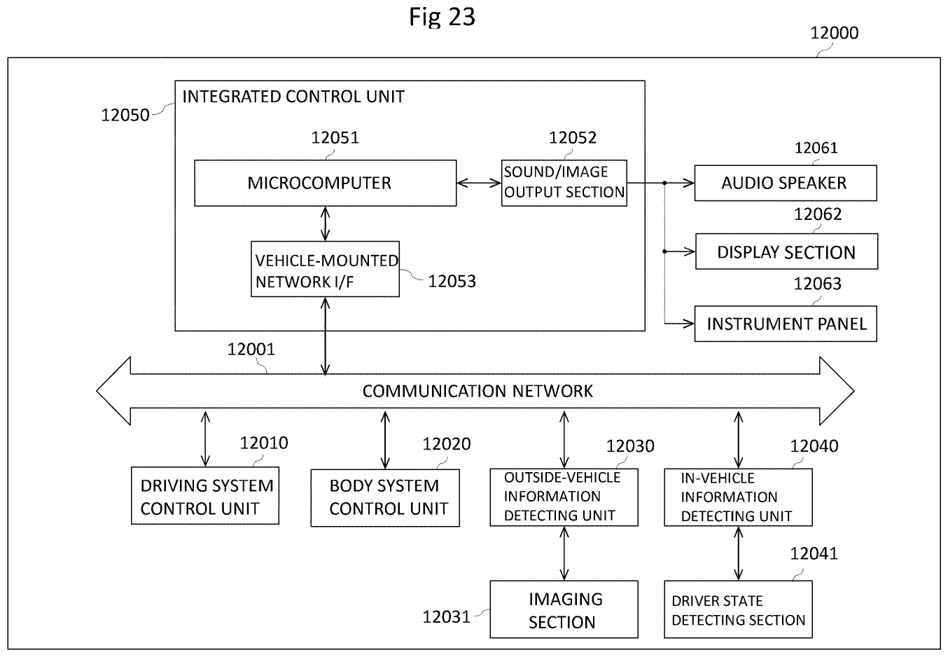

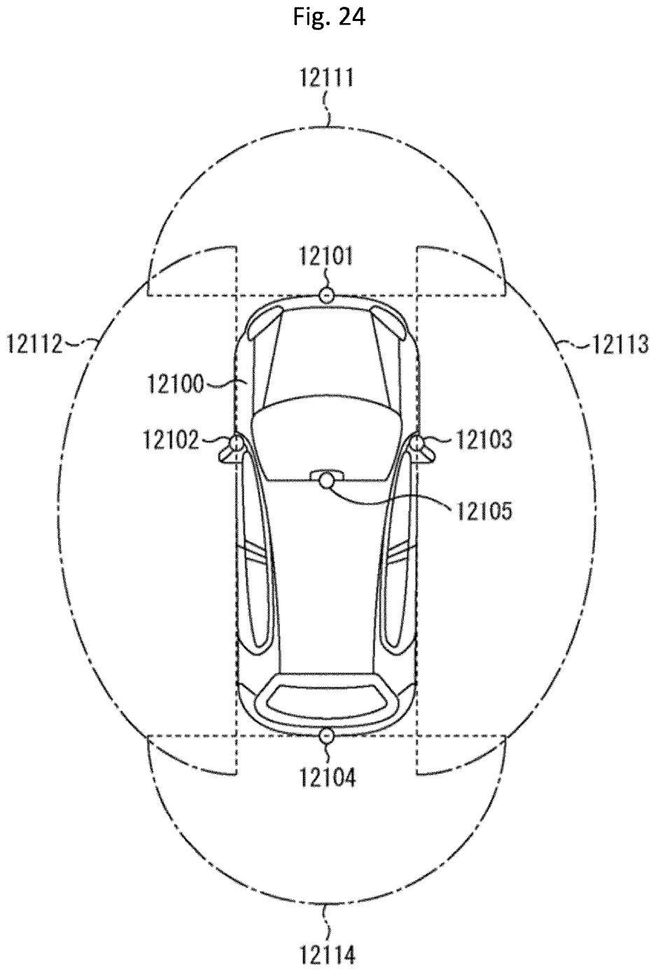

FIG. 23 is a block diagram depicting an example of schematic configuration of a vehicle control system as an example of a system to which the technology according to an embodiment of the present disclosure can be applied.

The vehicle control system 12000 includes a plurality of electronic control units connected to each other via a communication network 12001. In the example depicted in FIG. 23, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. The outside-vehicle information detecting unit 12030 can be connected with an imaging section 12031. The outside-vehicle information detecting unit 12030 makes the imaging section 12031 imaging an image of the outside of the vehicle and receives the imaged image. Based on the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 may be or may include a solid-state imaging device with an image sensor including pixel circuits according to the embodiments of the present disclosure. The light received by the imaging section 12031 may be visible light or may be invisible light such as infrared rays or the like.

The in-vehicle information detecting unit 12040 detects information about the inside of the vehicle and may be or may include an image sensor or a solid-state imaging device with an image sensor according to the embodiments of the present disclosure. The in-vehicle information detecting unit 12040 is, for example, connected with a driver state detecting section 12041 that detects the state of a driver. The driver state detecting section 12041, for example, includes a camera that includes the solid-stage imaging device and that is focused on the driver. Based on detection information input from the driver state detecting section 12041, the in-vehicle information detecting unit 12040 may calculate a degree of fatigue of the driver or a degree of concentration of the driver or may determine whether the driver is dozing.

The microcomputer 12051 can calculate a control target value for the driving force generating device, the steering mechanism, or the braking device based on the information about the inside or outside of the vehicle which information is obtained by the outside-vehicle information detecting unit 12030 or the in-vehicle information detecting unit 12040 and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 based on the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound or an image to an output device capable of visually or audible notifying information to an occupant of the vehicle or the outside of the vehicle. In the example of FIG. 23, an audio speaker 12061, a display section 12062, and an instrument panel 12063 are illustrated as the output device. The display section 12062 may, for example, include at least one of an on-board display or a head-up display.

FIG. 24 is a diagram depicting an example of the installation position of the imaging section 12031, wherein the imaging section 12031 may include imaging sections 12101, 12102, 12103, 12104, and 12105.

The imaging sections 12101, 12102, 12103, 12104, and 12105 are, for example, disposed at positions on a front nose, side-view mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the side view mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 24 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the side view mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, imaging element having pixels for phase difference detection or may include a ToF module including an image sensor or a solid-state imaging device with an image sensor assembly according to the embodiments of the present disclosure.

For example, the microcomputer 12051 can determine a distance to each three-dimensional object within the imaging ranges 12111 to 12114 and a temporal change in the distance (relative speed with respect to the vehicle 12100 on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062 and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The example of the vehicle control system to which the technology according to an embodiment of the present disclosure is applicable has been described above. By applying an image sensor assembly or a solid-state imaging device with an image sensor assembly according to the embodiments of the present disclosure, power consumption can be reduced.

Additionally, embodiments of the present technology are not limited to the above-described embodiments, but various changes can be made within the scope of the present technology without departing from the gist of the present technology.

The image sensor with pixel circuits according to the present disclosure may be any device used for analyzing and/or processing radiation such as visible light, infrared light, ultraviolet light, and X-rays. For example, a solid-state imaging device including an image sensor assembly according to the embodiments may be any electronic device in the field of traffic, the field of home appliances, the field of medical and healthcare, the field of security, the field of beauty, the field of sports, the field of agriculture, the field of image reproduction or the like.

Specifically, in the field of image reproduction, the solid-state imaging device including an image sensor assembly according to the embodiments may be a device for capturing an image to be provided for appreciation, such as a digital camera, a smart phone, or a mobile phone device having a camera function. In the field of traffic, for example, the solid-state imaging device including an image sensor assembly according to the embodiments may be integrated in an in-vehicle sensor that captures the front, rear, peripheries, an interior of the vehicle, etc. for safe driving such as automatic stop, recognition of a state of a driver, or the like, in a monitoring camera that monitors traveling vehicles and roads, or in a distance measuring sensor that measures a distance between vehicles or the like.

In the field of home appliances, the image sensor with pixel circuits according to the embodiments may be integrated in any type of sensor that can be used in devices provided for home appliances such as TV receivers, refrigerators, and air conditioners to capture gestures of users and perform device operations according to the gestures. Accordingly, the image sensor with pixel circuits according to the embodiments may be integrated in home appliances such as TV receivers, refrigerators, and air conditioners and/or in devices controlling the home appliances. Furthermore, in the field of medical and healthcare, the image sensor with pixel circuits according to the embodiments may be integrated in any type of sensor, e.g., a solid-state image device, provided for use in medical and healthcare, such as an endoscope or a device that performs angiography by receiving infrared light.

In the field of security, the image sensor with pixel circuits according to the embodiments can be integrated in a device provided for use in security, such as a monitoring camera for crime prevention or a camera for person authentication use. Furthermore, in the field of beauty, an image sensor with pixel circuits according to the embodiments can be used in a device provided for use in beauty, such as a skin measuring instrument that captures skin or a microscope that captures a probe. In the field of sports, an image sensor with pixel circuits according to the embodiments can be integrated in a device provided for use in sports, such as an action camera or a wearable camera for sport use or the like. Furthermore, in the field of agriculture, the image sensor with pixel circuits can be used in a device provided for use in agriculture, such as a camera for monitoring the condition of fields and crops.

The present technology can also be configured as described below:
[1] An image sensor assembly (70), including: a pixel circuit (100) comprising an amplifier transistor (102) electrically coupled to a data signal line (19); a buffer transistor (211) electrically connected to the data signal line (19), the buffer transistor (211) being configured to discharge the data signal line (19) in an AD conversion period; and a detector circuit (250) comprising a sensing path (261), wherein the amplifier transistor (102), the buffer transistor (211), and the sensing path (261) are electrically connected in series, and wherein the detector circuit (250) is configured to output an active comparator output signal when a current through the sensing path (261) exceeds a predefined threshold value.
[2] The image sensor assembly according to [1], further comprising: a ramp signal circuit (22), wherein the ramp signal circuit (22) is configured to generate a voltage ramp signal rmp comprising a ramp phase and wherein the voltage ramp signal rmp or a signal derived from the voltage ramp signal rmp is supplied to the gate of the buffer transistor (211).
[3] The image sensor assembly according to any of [1] to [2], further comprising: a sampling switch (213) configured to set the data signal line (19) to a predefined potential VPRD in a data line initialization period.
[4] The image sensor assembly according to [3], wherein the image sensor assembly (70) is configured to control the sampling switch (213) to connect the data signal line (19) to the predefined potential VPRD in a first portion of the data line initialization period, and to control the buffer transistor (211) and/or the pixel circuit (100) to charge or discharge the data signal line (19) to a data line set voltage in a second portion of the data line initialization period.
[5] The image sensor assembly according to any of [2] to [4], further comprising: a buffer autozero circuit (214) configured to obtain a pixel voltage ramp signal prmp applied to a gate of the buffer transistor (211) by subtracting a pixel-specific offset voltage from the voltage ramp signal rmp.
[6]

The image sensor assembly according to any of [2] to [5], further comprising: a buffer input capacitor (215) configured to receive the voltage ramp signal rmp at an input-side electrode, wherein an output-side electrode of the buffer input capacitor (215) is electrically connected to a gate of the buffer transistor (211); an autozero current source (216) configured to deliver a constant autozero current ILM through the amplifier transistor (102) of a selected pixel circuit (100) and the buffer transistor (211) in a ramp buffer autozero period; an autozero transistor (217) configured to connect the gate of the buffer transistor (211) with one side of a load path of the buffer transistor (211) in at least a portion of the ramp buffer autozero period.
[7] The image sensor assembly according to [6], further comprising: an autozero enable switch (218) electrically connecting the autozero current source (216) in series with a load path of the buffer transistor (211) in the ramp buffer autozero period, and to disconnect the autozero current source (216) from the buffer transistor (211) outside the ramp buffer autozero period.
[8] The image sensor assembly according to any of [1] to [7], further comprising: a comparator enable switch (219) configured to disconnect the sensing path (261) from a load path of the buffer transistor (211) outside AD conversion periods.
[9] The image sensor assembly according to any of [1] to [8], wherein the detector circuit (250) comprises a current mirror circuit (400) comprising a first leg and a second leg, wherein the first leg comprises a sensing transistor (262), wherein a load path between source and drain of the sensing transistor (262) forms at least part of the sensing path (261), and wherein the second leg comprises an output transistor (263) controlled by the current through the sensing path (261).
[10] The image sensor assembly according to [9], further comprising: a first load transistor (264) with a load path electrically connected between a gate of the sensing transistor (262) and the load path of the sensing transistor (262), and a second load transistor (265) with a load path electrically connected in series with a load path of the output transistor (263).
[11] The image sensor assembly according to any of [9] to [10], further comprising: a first leg current source (266) electrically connected in series with the sensing transistor (262), and a second leg current source (267) electrically connected in series with the output transistor (263).
[12] The image sensor assembly according to any of [9] to [11], further comprising: a current monitor circuit (270) configured to output a digital comparator output signal co, wherein the comparator output signal co has a first signal level when the current through the output transistor (263) is lower than a reference current, and wherein the comparator output signal co has a second signal level when the current through the output transistor (263) is higher than the reference current.
[13] The image sensor assembly according to any of [9] to [12], further comprising: an autozeroing circuit (280) configured to store information about an offset current flowing through the buffer transistor (211) in a comparator calibration period with no pixel circuit (100) selected, and to subtract the offset current from a current flowing through the buffer transistor (211) during discharge of the data signal line (19) in an AD conversion period.
[14] The image sensor assembly according to any of [9] to [13], further comprising: a ramp autozeroing capacitor (281) electrically connected between a gate of the sensing transistor (262) in the first leg and a gate of an output transistor (263) in the second leg, wherein the detector circuit (250) is configured to store the ramp autozero voltage across the ramp autozeroing capacitor (281).
[15] The image sensor assembly according to any of [9] to [14], further comprising: a ramp autozeroing switch (282) electrically connected between an output node (N1) and the gate of the output transistor (263), wherein the output node (N1) is between the second leg current source (267) and the load path of the second load transistor (265).
[16] The image sensor assembly according to any of [9] to [15], further comprising: a first leg switch (291) configured to disable the first leg current source (266) at least outside the AD conversion periods, and/or a second leg switch (292) configured to disable the second leg current source (266) at least outside the AD conversion periods.
[17] The image sensor assembly according to any of [1] to [16], wherein each pixel circuit (100) comprises a floating diffusion capacitance (108) electrically connected between a gate of the amplifier transistor (102) and a capacitance control line (15).
[18] The image sensor assembly according to any of [1] to [17], further comprising: a sampling switch (213) configured to connect the data signal line (19) to a positive pixel supply potential VDDH.
[19] The image sensor assembly according to any of [1] to [18], further comprising: a row noise reduction unit (240) configured to generate a noise compensation current from a positive pixel supply voltage VDDH electrically connected to the amplifier transistor (102) and apply the noise compensation current to the data signal line (19) to compensate a noise-induced current generated by power supply noise passed through the pixel circuit (100) to the data signal line (19).
[20] The image sensor assembly according to [19], wherein the row noise reduction unit (240) comprises a noise compensation signal generation circuit (24) and controllable current sources (241), wherein the noise compensation signal generation circuit (24) is configured to generate a noise compensation signal qualitatively replicating the power supply noise, and wherein each controllable current source (241) is configured to generate the noise compensation current for a data signal line (19) in response to the noise compensation signal.
[21] The image sensor assembly according to [20], wherein a gain of the noise compensation signal generation circuit (24) is adjustable.
[22] The image sensor assembly according to [21], further comprising: a first digital pixel memory (411) configured to store count values latched in response to the active comparator output signal, wherein the count values represent pixel noise values obtained in a reset phase; and a row noise estimation block (422) configured to adjust the gain of the noise compensation signal generation circuit (24) based on the pixel noise values.
[23] The image sensor assembly according to [22], wherein the row noise estimation block (422) is configured to adjust the gain of the noise compensation signal generation circuit (24) to minimize a variance of a distribution of the pixel noise values.

1. An image sensor assembly, comprising:
a pixel circuit comprising an amplifier transistor electrically coupled to a data signal line;
a buffer transistor electrically connected to the data signal line, the buffer transistor being configured to discharge the data signal line in an AD conversion period; and
a detector circuit comprising a sensing path, wherein the amplifier transistor, the buffer transistor, and the sensing path are electrically connected in series, and wherein the detector circuit is configured to output an active comparator output signal when a current through the sensing path exceeds a predefined threshold value.

2. The image sensor assembly according to claim 1, further comprising:
a ramp signal circuit, wherein the ramp signal circuit is configured to generate a voltage ramp signal rmp comprising a ramp phase and wherein the voltage ramp signal rmp or a signal derived from the voltage ramp signal rmp is supplied to the gate of the buffer transistor.

3. The image sensor assembly according to claim 1, further comprising:
a sampling switch configured to set the data signal line to a predefined potential VPRD in a data line initialization period.

4. The image sensor assembly according to claim 3,
wherein the image sensor assembly is configured to control the sampling switch to connect the data signal line to the predefined potential VPRD in a first portion of the data line initialization period, and to control the buffer transistor and/or the pixel circuit to charge or discharge the data signal line to a data line set voltage in a second portion of the data line initialization period.

5. The image sensor assembly according to claim 2, further comprising:
a buffer autozero circuit configured to obtain a pixel voltage ramp signal prmp applied to a gate of the buffer transistor by subtracting a pixel-specific offset voltage from the voltage ramp signal rmp.

6. The image sensor assembly according to claim 2, further comprising:
a buffer input capacitor configured to receive the voltage ramp signal rmp at an input-side electrode, wherein an output-side electrode of the buffer input capacitor is electrically connected to a gate of the buffer transistor;
an autozero current source configured to deliver a constant autozero current ILM through the amplifier transistor of a selected pixel circuit and the buffer transistor in a ramp buffer autozero period;
an autozero transistor configured to connect the gate of the buffer transistor with one side of a load path of the buffer transistor in at least a portion of the ramp buffer autozero period.

7. The image sensor assembly according to claim 6, further comprising:
an autozero enable switch electrically connecting the autozero current source in series with a load path of the buffer transistor in the ramp buffer autozero period, and to disconnect the autozero current source from the buffer transistor outside the ramp buffer autozero period.

8. The image sensor assembly according to claim 1, further comprising:
a comparator enable switch configured to disconnect the sensing path from a load path of the buffer transistor outside AD conversion periods.

9. The image sensor assembly according to claim 1,
wherein the detector circuit comprises a current mirror circuit comprising a first leg and a second leg, wherein the first leg comprises a sensing transistor, wherein a load path between source and drain of the sensing transistor forms at least part of the sensing path, and wherein the second leg comprises an output transistor controlled by the current through the sensing path.

10. The image sensor assembly according to claim 9, further comprising:
a first load transistor with a load path electrically connected between a gate of the sensing transistor and the load path of the sensing transistor, and a second load transistor with a load path electrically connected in series with a load path of the output transistor.

11. The image sensor assembly according to claim 9, further comprising:
a first leg current source electrically connected in series with the sensing transistor, and a second leg current source electrically connected in series with the output transistor.

12. The image sensor assembly according to claim 9, further comprising:
a current monitor circuit configured to output a digital comparator output signal co, wherein the comparator output signal co has a first signal level when the current through the output transistor is lower than a reference current, and wherein the comparator output signal co has a second signal level when the current through the output transistor is higher than the reference current.

13. The image sensor assembly according to claim 9, further comprising:
an autozeroing circuit configured to store information about an offset current flowing through the buffer transistor in a comparator calibration period with no pixel circuit selected, and to subtract the offset current from a current flowing through the buffer transistor during discharge of the data signal line in an AD conversion period.

14. The image sensor assembly according to claim 9, further comprising:
a ramp autozeroing capacitor electrically connected between a gate of the sensing transistor in the first leg and a gate of an output transistor in the second leg, wherein the detector circuit is configured to store the ramp autozero voltage across the ramp autozeroing capacitor.

15. The image sensor assembly according to claim 9, further comprising:
a ramp autozeroing switch electrically connected between an output node and the gate of the output transistor, wherein the output node is between the second leg current source and the load path of the second load transistor.

16. The image sensor assembly according to claim 9, further comprising:
a first leg switch configured to disable the first leg current source at least outside the AD conversion periods, and/or a second leg switch configured to disable the second leg current source at least outside the AD conversion periods.

17. The image sensor assembly according to claim 1,
wherein each pixel circuit comprises a floating diffusion capacitance electrically connected between a gate of the amplifier transistor and a capacitance control line.

18. The image sensor assembly according to claim 1, further comprising:
a sampling switch configured to connect the data signal line to a positive pixel supply potential VDDH.

19. The image sensor assembly according to claim 1, further comprising:
a row noise reduction unit configured to generate a noise compensation current from a positive pixel supply voltage VDDH electrically connected to the amplifier transistor and apply the noise compensation current to the data signal line to compensate a noise-induced current generated by power supply noise passed through the pixel circuit to the data signal line.

20. The image sensor assembly according to claim 19,
wherein the row noise reduction unit comprises a noise compensation signal generation circuit and controllable current sources, wherein the noise compensation signal generation circuit is configured to generate a noise compensation signal qualitatively replicating the power supply noise, and wherein each controllable current source is configured to generate the noise compensation current for a data signal line in response to the noise compensation signal.

21. The image sensor assembly according to claim 20,
wherein a gain of the noise compensation signal generation circuit is adjustable.

22. The image sensor assembly according to claim 21, further comprising:
a first digital pixel memory configured to store count values latched in response to the active comparator output signal, wherein the count values represent pixel noise values obtained from a reset phase; and
a row noise estimation block configured to adjust the gain of the noise compensation signal generation circuit based on the pixel noise values.

23. The image sensor assembly according to claim 22,
wherein the row noise estimation block is configured to adjust the gain of the noise compensation signal generation circuit to minimize a variance of the pixel noise values.
